(19) United States
(12) Patent Application Publication
(10) Pub. No.: US 2026/0362659 A1
(43) Pub. Date: Nov. 12, 2026

(54) POWER CONVERSION DEVICE, ELECTRIC VEHICLE DRIVE DEVICE, AND POWER CONVERSION DEVICE MANUFACTURING METHOD

(71) Applicant: MITSUBISHI ELECTRIC MOBILITY CORPORATION, Tokyo (JP)

(72) Inventors: Shingo KITAGAWA, Tokyo (JP); Daisuke SASAKI, Tokyo (JP); Isao TOTTORI, Tokyo (JP); Naoya ABE, Tokyo (JP)

(73) Assignee: MITSUBISHI ELECTRIC MOBILITY CORPORATION, Tokyo (JP)

(21) Appl. No.: 19/487,142

(22) PCT Filed: Jun. 5, 2023
(86) PCT No.: PCT/JP2023/020806

§ 371 Date: Nov. 24, 2025

(51) Int. Cl. H05K 7/20; B60L 15/00; H02M 7/00; H02M 7/537; H05K 7/14

(52) U.S. Cl. CPC H05K 7/20927; B60L 15/007; H02M 7/003; H02M 7/537; H05K 7/14324

(57) ABSTRACT

A power conversion device includes: one or a plurality of power modules; a control board; at least one electrical component among electrical components that are a smoothing capacitor, a reactor, a boost converter unit, a buck converter unit, and a transmission control unit; a busbar assembly; and a cooler having a first cooling surface, a second cooling surface, and a coolant flow path. Each power module, the smoothing capacitor, the reactor, the boost converter unit, the buck converter unit, the transmission control unit, and the busbar assembly are heat generation components. The first cooling surface and the second cooling surface are provided on both sides of the coolant flow path parallelly to each other. At least one of the heat generation components is thermally connected to the first cooling surface. At least one of the heat generation components is thermally connected to the second cooling surface.

### TECHNICAL FIELD

The present disclosure relates to a power conversion device, an electric vehicle drive device, and a power conversion device manufacturing method.

### BACKGROUND ART

In recent years, electric automobiles or hybrid automobiles have been mounted with motors as power sources for the vehicles. Therefore, these vehicles generally include power conversion devices such as inverters in order to control power to be supplied to the motors. Configurations of such power conversion devices mounted in vehicles have been disclosed (see, for example, Patent Document 1). A power conversion device in Patent Document 1 has a main section composed of: a power module having a built-in semiconductor element such as an IGBT; a drive circuit which drives the power module; a control circuit which controls these components; a smoothing capacitor which smooths an input voltage of the power module; and a cooler having a coolant flow path formed therein.

However, the power conversion device disclosed in Patent Document 1 cannot exhibit a function as a product without incorporating the main components into a housing, and thus it is difficult to check a function and a performance of the power conversion device before the incorporation into a housing. Therefore, this difficulty leads to a disadvantage in terms of improvement of productivity for the power conversion device and leads to a problem also in terms of ensuring the quality thereof.

Configurations each allowing a function and a performance of a power conversion device to be checked before incorporation into a housing have been disclosed (see, for example, Patent Document 2). A power conversion device disclosed in Patent Document 2 is a high-voltage unit completed as a unit that can exhibit minimum necessary main functions, i.e., a cooling function and an inverter function, required for the power conversion device and enables inspection of both functions before being incorporated into a housing.

### CITATION LIST

### Patent Document

Patent Document 1: Japanese Laid-Open Patent Publication No. 2019-170158
Patent Document 2: Japanese Laid-Open Patent Publication No. 2017-135919

### SUMMARY OF THE INVENTION

### Problem to be Solved by the Invention

In the above Patent Document 2, the functions of the power conversion device are exhibited before incorporation into a housing, whereby the functions can be inspected before incorporation into a housing. However, in the configuration of the disclosed power conversion device, a water-cooling jacket has one surface on which a power module is disposed, and a busbar and a smoothing capacitor are placed on an upper portion of the power module. Thus, a heat generation component (e.g., the smoothing capacitor) other than the power module cannot be thermally connected to the water-cooling jacket in a state where a sufficient heat dissipation area is ensured. Therefore, a problem arises in that the cooling performance of the power conversion device decreases.

Considering this, an object of the present disclosure is to provide a power conversion device that has excellent cooling performance with productivity for the power conversion device being improved.

### Means to Solve the Problem

A power conversion device according to the present disclosure includes: one or a plurality of power modules, each of the power modules having one or a plurality of semiconductor elements and being connected to a power supply connection terminal to be connected to a DC power supply; a control board which controls switching operations of the semiconductor elements; at least one electrical component among an electrical component that is a smoothing capacitor which smooths an input voltage to be inputted from the DC power supply to the power module and electrical components that are a reactor, a boost converter unit, a buck converter unit, and a transmission control unit electrically connected to the power module; a busbar assembly having a busbar establishing electrical connection in at least one interval among an interval between the power supply connection terminal and the power module, an interval between the power supply connection terminal and the at least one electrical component, and an interval between the power module and the at least one electrical component; and a cooler having a first cooling surface, a second cooling surface on an opposite side to the first cooling surface, and a coolant flow path which is formed in the cooler. The power module, the smoothing capacitor, the reactor, the boost converter unit, the buck converter unit, the transmission control unit, and the busbar assembly are heat generation components. The first cooling surface and the second cooling surface are provided on both sides of the coolant flow path parallelly to each other. At least one of the heat generation components is thermally connected to the first cooling surface. At least one of the heat generation components is thermally connected to the second cooling surface.

### Effect of the Invention

The power conversion device according to the present disclosure includes: one or a plurality of power modules; a control board; at least one electrical component among electrical components that are a smoothing capacitor, a reactor, a boost converter unit, a buck converter unit, and a transmission control unit; a busbar assembly having a busbar; and a cooler having a first cooling surface, a second cooling surface, and a coolant flow path which is formed in the cooler. Each power module, the smoothing capacitor, the reactor, the boost converter unit, the buck converter unit, the transmission control unit, and the busbar assembly are heat generation components. The first cooling surface and the second cooling surface are provided on both sides of the coolant flow path parallelly to each other. At least one of the heat generation components is thermally connected to the first cooling surface. At least one of the heat generation components is thermally connected to the second cooling surface. Consequently, it is possible to thermally connect, in addition to one of the heat generation components, another one of the heat generation components to the cooler without upsizing the cooler. Since both of the two heat generation components are thermally connected to the cooler, heat dissipation properties of the two heat generation components are improved, whereby a power conversion device having excellent cooling performance can be obtained. In addition, the power conversion device is completed as an integrated unit that can exhibit main functions (e.g., an inverter function and a cooling function) required for the power conversion device and enables inspection of the main functions without being incorporated into a housing or the like. Consequently, productivity for the power conversion device 1 can be improved.

### BRIEF DESCRIPTION OF THE DRAWINGS

FIG. 1 is a side view schematically showing a power conversion device according to embodiment 1.

FIG. 2 is a side view schematically showing the power conversion device according to embodiment 1.

FIG. 3 shows an example of the circuit configuration of a power converter according to embodiment 1.

FIG. 4 is a side view schematically showing another power conversion device according to embodiment 1.

FIG. 5 is a side view schematically showing the other power conversion device according to embodiment 1.

FIG. 6 shows a manufacturing process for the power conversion device according to embodiment 1.

FIG. 7 is a side view schematically showing a power conversion device according to embodiment 2.

FIG. 8 is a side view schematically showing the power conversion device according to embodiment 2.

FIG. 9 is a side view schematically showing another power conversion device according to embodiment 2.

FIG. 10 is a side view schematically showing the other power conversion device according to embodiment 2.

FIG. 11 shows a manufacturing process for the power conversion device according to embodiment 2.

FIG. 12 is a side view schematically showing a power conversion device according to embodiment 3.

FIG. 13 is a side view schematically showing the power conversion device according to embodiment 3.

FIG. 14 is a side view schematically showing another power conversion device according to embodiment 3.

FIG. 15 is a side view schematically showing the other power conversion device according to embodiment 3.

FIG. 16 is a side view schematically showing a power conversion device according to embodiment 4.

FIG. 17 is a side view schematically showing the power conversion device according to embodiment 4.

FIG. 18 is a side view schematically showing another power conversion device according to embodiment 4.

FIG. 19 is a side view schematically showing the other power conversion device according to embodiment 4.

FIG. 20 is a side view schematically showing still another power conversion device according to embodiment 4.

FIG. 21 is a side view schematically showing a power conversion device according to embodiment 5.

FIG. 22 is a side view schematically showing the power conversion device according to embodiment 5.

FIG. 23 is a side view schematically showing another power conversion device according to embodiment 5.

FIG. 24 is a side view schematically showing the other power conversion device according to embodiment 5.

FIG. 25 is a side view schematically showing a power conversion device according to embodiment 6.

FIG. 26 is a side view schematically showing the power conversion device according to embodiment 6.

FIG. 27 is a side view schematically showing another power conversion device according to embodiment 6.

FIG. 28 is a side view schematically showing the other power conversion device according to embodiment 6.

FIG. 29 is a side view schematically showing a power conversion device according to embodiment 7.

FIG. 30 is a side view schematically showing the power conversion device according to embodiment 7.

FIG. 31 is a side view schematically showing another power conversion device according to embodiment 7.

FIG. 32 is a side view schematically showing the other power conversion device according to embodiment 7.

FIG. 33 is a diagram schematically showing an electric vehicle drive device according to embodiment 8.

### DESCRIPTION OF EMBODIMENTS

Hereinafter, power conversion devices, an electric vehicle drive device, and power conversion device manufacturing methods according to embodiments of the present disclosure will be described with reference to the drawings. Description will be given while the same or corresponding members and portions in the drawings are denoted by the same reference characters.

### Embodiment 1

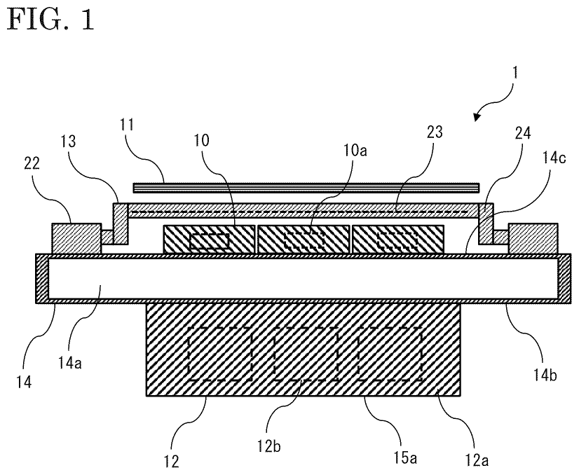

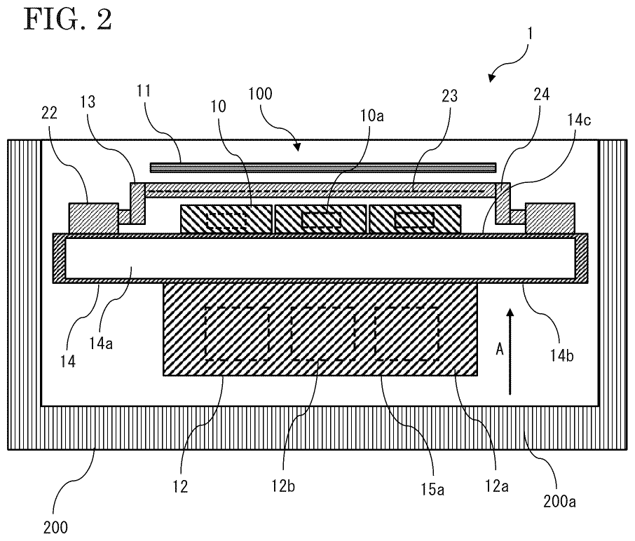

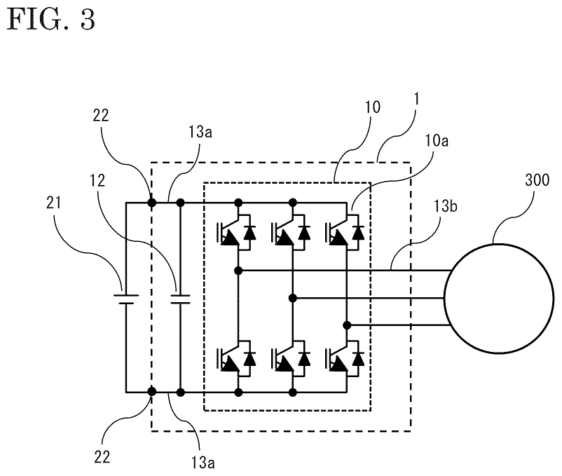

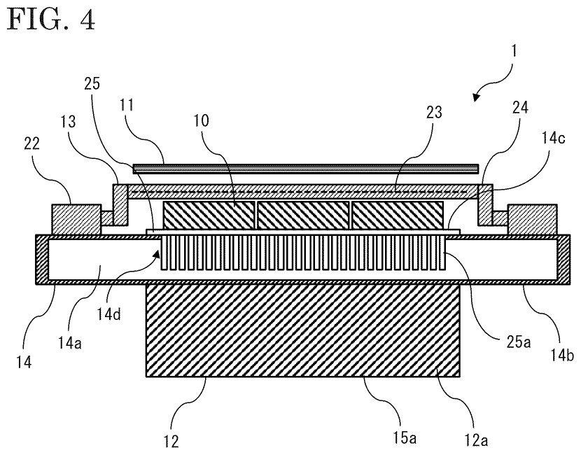

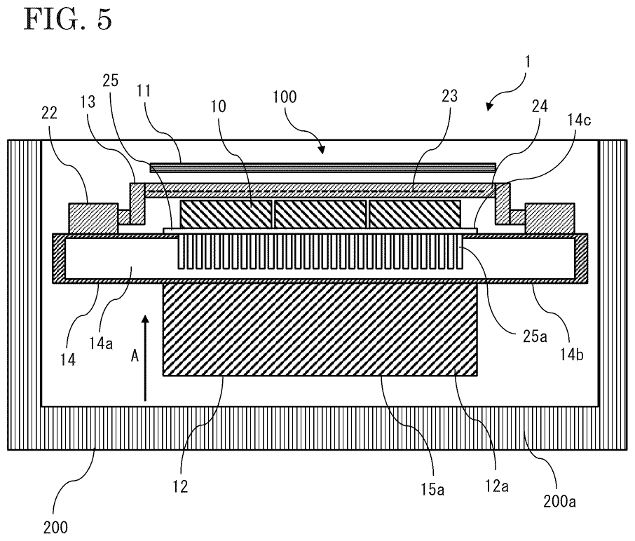

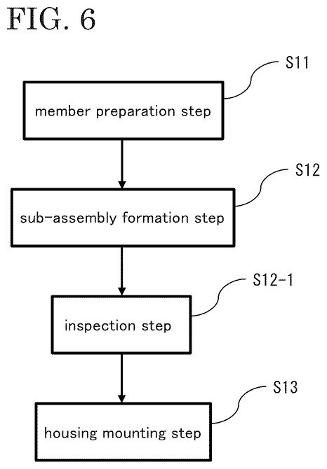

FIG. 1 is a side view schematically showing a power conversion device 1 according to embodiment 1, with a side wall of a cooler 14 being partially removed. FIG. 2 is a side view schematically showing the power conversion device 1, with a peripheral wall of a housing 200 being partially removed. FIG. 3 shows an example of the circuit configuration of the power conversion device 1. FIG. 4 is a side view schematically showing another power conversion device 1 according to embodiment 1, with the side wall of the cooler 14 being partially removed. FIG. 5 is a side view schematically showing the other power conversion device 1, with the peripheral wall of the housing 200 being partially removed. FIG. 6 shows a manufacturing process for the power conversion device 1. The power conversion device 1 is a device for converting an input current from DC into AC or from AC into DC or converting an input voltage to a different voltage. In the present disclosure, the power conversion device 1 will be described as an inverter for converting DC power into AC power and supplying the AC power to a drive motor of a hybrid automobile or an electric automobile. However, the power conversion device 1 according to the present disclosure is not limited to such an inverter.

### Circuit Configuration of Power Conversion Device 1

A schematic of the circuit configuration of the power conversion device 1 will be described with reference to FIG. 3. The power conversion device 1 includes a power module 10 and a smoothing capacitor 12 which smooths an input voltage to be inputted from a DC power supply 21 to the power module 10. The power conversion device 1 is connected to the DC power supply 21 which is present outside. The power conversion device 1 includes busbars 13a through which DC power flows and busbars 13b through which AC power flows. The smoothing capacitor 12 is electrically connected to the busbars 13a. The power module 10 is electrically connected to the busbars 13a and the busbars 13b. The power module 10 has one or a plurality of semiconductor elements 10a and is connected to power supply connection terminals 22 connected to the DC power supply 21. Although the power module 10 in FIG. 3 has six semiconductor elements 10a, the number of the semiconductor elements 10a is not limited thereto. The semiconductor elements 10a perform power conversion between DC power and AC power. The AC power is outputted from the busbars 13b to a drive motor 300 to drive a rotating electric machine including the drive motor 300. The power conversion device 1 may be configured to convert AC power outputted from a generator into DC power in order to charge the DC power supply 21.

As each of the semiconductor elements 10a, a power control semiconductor element such as a metal-oxide-semiconductor field-effect transistor (MOSFET) or an insulated-gate bipolar transistor (IGBT), a flyback diode, or the like is used. The semiconductor element 10a is not limited thereto and may be another semiconductor element such as a bipolar transistor. Alternatively, the semiconductor element 10a may be a reverse conducting IGBT (RC-IGBT) in which a switching element and a flyback diode have been integrated with each other.

The semiconductor element 10a is formed on a semiconductor substrate formed from a material such as silicon, silicon carbide, or gallium nitride. For the semiconductor element 10a, a wide-bandgap semiconductor element having a wider bandgap than silicon may be used. In the case of using, for example, a MOSFET formed from silicon carbide which is a wide-bandgap semiconductor element, this MOSFET can be caused to have a larger temporal change amount di/dt of current generated upon switching than a MOSFET formed from silicon. In addition, such a wide-bandgap semiconductor element has a low ON resistance, sustains little loss, and generates little heat, and thus the chip area can be decreased. Since the chip area is decreased, the power module 10 can be downsized.

### Configuration of Power Conversion Device 1

A configuration of the power conversion device 1 will be described with reference to FIG. 1. The power conversion device 1 includes one or a plurality of the power modules 10, a control board 11, at least one electrical component, a busbar assembly 13, and the cooler 14. Each of the power modules 10 has the one or plurality of semiconductor elements 10a and is connected to the power supply connection terminals 22 to be connected to the DC power supply 21. Although the power conversion device 1 in the present embodiment includes three such power modules 10, the number of the power modules 10 is not limited thereto. The number of the semiconductor elements 10a of each of the power modules 10 is, for example, two. The control board 11 controls switching operations of the semiconductor elements 10a.

In the present embodiment, the power conversion device 1 includes, as the at least one electrical component, the smoothing capacitor 12 which smooths an input voltage to be inputted from the DC power supply 21 to the power module 10. The at least one electrical component is not limited to the smoothing capacitor 12. Other examples of the at least one electrical component are a reactor, a boost converter unit, a buck converter unit, and a transmission control unit electrically connected to the power module 10. The other examples of the at least one electrical component will be described later.

The busbar assembly 13 has busbars 13a establishing electrical connection in at least one interval among an interval between the power supply connection terminals 22 and the power module 10, an interval between the power supply connection terminals 22 and the at least one electrical component, and an interval between the power module 10 and the at least one electrical component. In the present embodiment, the busbar assembly 13 has busbars 13a establishing electrical connection in the interval between the power supply connection terminals 22 and the power module 10, the interval between the power supply connection terminals 22 and the smoothing capacitor 12, and the interval between the power module 10 and the smoothing capacitor 12. In FIG. 1, the busbar assembly 13 has both of the busbars 13a and 13b shown in FIG. 3. In FIG. 1 and FIG. 2, the busbars 13a and 13b are schematically indicated as busbars 23 by a broken line collectively, and the busbars 13a and 13b are not individually shown in FIG. 1 or FIG. 2.

The cooler 14 has a first cooling surface 14b, a second cooling surface 14c on an opposite side to the first cooling surface 14b, and a coolant flow path 14a which is formed in the cooler 14. The power module 10, the smoothing capacitor 12, the reactor, the boost converter unit, the buck converter unit, the transmission control unit, and the busbar assembly 13 are heat generation components. The first cooling surface 14b and the second cooling surface 14c are provided on both sides of the coolant flow path 14a parallelly to each other. At least one of the heat generation components is thermally connected to the first cooling surface 14b. At least one of the heat generation components is thermally connected to the second cooling surface 14c. In the present embodiment, the smoothing capacitor 12 as a heat generation component is thermally connected to the first cooling surface 14b, and the power module 10 as a heat generation component is thermally connected to the second cooling surface 14c.

This configuring makes it possible to thermally connect, in addition to the power module 10 as one of the heat generation components, another one of the heat generation components to the cooler 14 without upsizing the cooler 14. Since both of the two beat generation components are thermally connected to the cooler 14, heat dissipation properties of the two heat generation components are improved, whereby a power conversion device 1 having excellent cooling performance can be obtained. In addition, since the heat dissipation properties of the two heat generation components are improved, both of the two heat generation components can be downsized. Since both of the two heat generation components are downsized, the power conversion device 1 can be downsized.

The power conversion device 1 is accommodated in a housing or the like and is mounted in a hybrid automobile or an electric automobile. The power conversion device 1 has a power conversion function and a cooling function and enables inspection of the power conversion function and the cooling function. The power conversion device 1 shown in FIG. 1 is completed as an integrated unit that can exhibit main functions (e.g., the inverter function and the cooling function) required for the power conversion device 1 and enables inspection of the main functions without being incorporated into a housing or the like. Consequently, productivity for the power conversion device 1 can be improved. In addition, in a case where the power conversion device 1 is mounted to a drive motor or an e-Axle, upsizing of inspection equipment for the power conversion device 1 can be suppressed. In addition, it becomes easy to connect an inspection probe, whereby the accuracy of inspection of the power conversion device 1 can be improved. Since the accuracy of inspection of the power conversion device 1 is improved, the quality of the power conversion device 1 can be ensured.

### Housing 200

A configuration in which the power conversion device 1 shown in FIG. 1 is accommodated in the housing 200 will be described with reference to FIG. 2. The power conversion device 1 shown in FIG. 1 is referred to as “sub-assembly 100” in FIG. 2. The power conversion device 1 includes the housing 200. The heat generation components, the control board 11, and the cooler 14 are accommodated in the housing 200. In the present embodiment, the heat generation components are each of the power modules 10, the smoothing capacitor 12, and the busbar assembly 13 as described above. The first cooling surface 14b and the second cooling surface 14c are orthogonal to a direction of a normal to an opposed surface of the housing 200 opposed to the first cooling surface 14b or the second cooling surface 14c. In the present embodiment, the housing 200 is formed in a shape of a tube with a bottom, and the opposed surface of the housing 200 is an inner surface of a bottom wall 200a of the housing 200. The shape of the housing 200 is not limited to the shape of a tube with a bottom. However, in the case where the housing 200 has the shape of a tube with a bottom, the housing 200 can be easily manufactured. The direction of the normal to the inner surface of the bottom wall 200a is the direction indicated by the arrow A in FIG. 2. In the present embodiment, the smoothing capacitor 12 is disposed on a side in a mounting direction of the sub-assembly 100 to the housing 200 (a direction opposite to the normal).

This configuring causes the mounting direction of the sub-assembly 100 to the housing 200 to be a direction orthogonal to the first cooling surface 14b and the second cooling surface 14c, whereby the sub-assembly 100 can be easily mounted to the housing 200. Since the sub-assembly 100 is easily mounted to the housing 200, the productivity for the power conversion device 1 can be improved.

### Constituent Members of Power Conversion Device 1

The constituent members of the power conversion device 1 will be described in detail. The housing 200 is formed from, for example, aluminum or an aluminum alloy. By using aluminum or an aluminum alloy and performing die casting to manufacture the housing 200, the housing 200 can be easily manufactured. In addition, the weight of the housing 200 can be decreased. The housing 200 may be integrated with an external device, and the external device may be, for example, a drive motor or an e-Axle.

The cooler 14 is formed from, for example, aluminum or an aluminum alloy. By using aluminum or an aluminum alloy and performing die casting to manufacture the cooler 14, the cooler 14 can be easily manufactured. In addition, the weight of the cooler 14 can be decreased. A coolant (not shown) is caused to flow through the coolant flow path 14a. The coolant is, for example, a long life coolant (LLC). The cooler 14 in the present embodiment is a water-cooling-type cooler.

The coolant flow path 14a is, for example, formed parallelly to the first cooling surface 14b and the second cooling surface 14c. By causing the coolant to flow parallelly to the first cooling surface 14b and the second cooling surface 14c, the first cooling surface 14b and the second cooling surface 14c can be efficiently cooled. The cooler 14 has an inlet and an outlet (not shown) for the coolant. Through the inlet or the outlet for the coolant, the coolant flows from the outside of the housing 200 into the cooler 14 or flows from the cooler 14 to the outside of the housing 200. The sub-assembly 100 is fixed to the housing 200 by using, for example, a connection boss (not shown) provided to the cooler 14.

Each of the semiconductor elements 10a of the power module 10 is, for example, an IGBT as described above. The power module 10 has a plurality of high-voltage main circuit terminals and a plurality of signal terminals (not shown). The high-voltage main circuit terminals are connected to the busbars 23 of the busbar assembly 13. The plurality of signal terminals are connected to the control board 11. The power module 10 generates heat as a result of high-speed switching operations of the semiconductor elements 10a. The heat generated in the power module 10 is transmitted via the cooler 14 to the coolant flowing through the coolant flow path 14a.

Although the power module 10 is directly thermally connected to the cooler 14 in the present embodiment, no limitation thereto is made. The power module 10 may be thermally connected to the cooler 14 with a heat dissipator therebetween. The heat dissipator is formed from a material having excellent heat conducting properties, and the material is, for example, grease, a solder, a gap filler, or a compound. By thermally connecting the power module 10 to the cooler 14 with the heat dissipator therebetween, the power module 10 can be further efficiently cooled.

The busbar assembly 13 has a plurality of the busbars 23 and a holding member 24. The busbars 23 are formed from, for example, copper having excellent electrical conducting properties. The holding member 24 is formed from a resin having insulation properties. The busbars 23 and the holding member 24 are integrated with each other through insert molding. Through the integral molding, the busbars 23 are held by the holding member 24. In addition, the holding member 24 performs insulation in each of intervals between the plurality of busbars 23.

The busbars 23 are electrically connected to the high-voltage main circuit terminals extending from the power module 10. The connection between the busbars 23 and the high-voltage main circuit terminals is achieved through, for example, fastening with screws or TIG welding. In addition, the busbars 13a as DC lines among the busbars 23 are electrically connected to the smoothing capacitor 12, and the busbars 13b as AC lines among the busbars 23 are electrically connected to the drive motor 300 (not shown in FIG. 1).

In the present embodiment, the busbar assembly 13 is disposed on an opposite side to the cooler 14 side of the power module 10. Also, although the busbar assembly 13 has both of the busbars 13a and 13b in the present embodiment, no limitation thereto is made. A busbar assembly having the busbars 13a and a busbar assembly having the busbars 13b may be individually provided. Also, although the busbar assembly 13 is formed through insert molding in the present embodiment, no limitation thereto is made. The busbar assembly 13 may be formed of the busbars 23 and an insulating member provided around the busbars 23 without performing insert molding. The insulating member is formed from, for example, insulation paper or a resin. The busbars 13a may be formed directly on the power module 10 by using parallel flat plates.

The control board 11 has a drive circuit and a control circuit. The drive circuit drives the power module 10. The control circuit controls the drive circuit. In the present embodiment, the control board 11 is disposed on an opposite side to the power module 10 side of the busbar assembly 13. By disposing the control board 11 at such a location, influence of heat from the power module 10 to the control board 11 can be suppressed. However, the location of the control board 11 is not limited thereto. For example, the control board 11 may be disposed between the busbar assembly 13 and the power module 10 or at the same height as that of the busbar assembly 13.

Although the control board 11 is formed of one board as shown in FIG. 1 in the present embodiment, no limitation thereto is made. The control board 11 may be divided into a plurality of boards in consideration of functionality, ease of layout, productivity, and the like.

For example, the control board 11 may be divided into control boards for the drive circuit and the control circuit. In the present embodiment, the control board 11 is fixed to a board fixation boss (not shown) provided to the busbar assembly 13. The part to which the control board 11 is fixed is not limited to the busbar assembly 13 and may be, for example, the cooler 14 or the smoothing capacitor 12.

The smoothing capacitor 12 smooths an input voltage of the power module 10. The smoothing capacitor 12 has a case 12a, a plurality of capacitor elements 12b, and a plurality of capacitor busbars (not shown). The plurality of capacitor elements 12b are accommodated in the case 12a. The case 12a is formed from, for example, a synthetic resin.

The smoothing capacitor 12 as a heat generation component is thermally connected to the first cooling surface 14b or the second cooling surface 14c. In the present embodiment, the smoothing capacitor 12 is thermally connected to the first cooling surface 14b. This configuring makes it possible to thermally connect the smoothing capacitor 12 having a large heat generation amount to the cooler 14. Since the smoothing capacitor 12 is thermally connected to the cooler 14, heat dissipation properties of the smoothing capacitor 12 are improved, whereby a power conversion device 1 having excellent cooling performance can be obtained. In addition, since the heat dissipation properties of the smoothing capacitor 12 are improved, the capacitor elements 12b of the smoothing capacitor 12 can be downsized. Since the capacitor elements 12b are downsized, the smoothing capacitor 12 is downsized, whereby the power conversion device 1 can be downsized.

As each of the capacitor elements 12b, for example, a wound film capacitor is used. The wound film capacitor is flattened into an oval shape. The capacitor element 12b is sealed in the case 12a by filling the case 12a with an epoxy resin.

Each of the capacitor busbars has one end connected to the capacitor element 12b. The capacitor busbar has another end protruding to the outside of the case 12a and connected to the busbars 13a in the busbar assembly 13. The connection between the other end of the capacitor busbar and the busbars 13a is achieved by, for example, fastening with screws or TIG welding. Alternatively, the other end of the capacitor busbar may be electrically connected to the high-voltage main circuit terminals of the power module 10 through, for example, fastening with screws or TIG welding.

The smoothing capacitor 12 generates heat through Joule heating by the own equivalent series resistance (ESR) and heat reception from the power module 10. The heat generated in the smoothing capacitor 12 is transmitted via the cooler 14 to the coolant flowing through the coolant flow path 14a.

Although the smoothing capacitor 12 is directly thermally connected to the cooler 14 in the present embodiment, no limitation thereto is made. The smoothing capacitor 12 may be thermally connected to the cooler 14 with a heat dissipator therebetween. The heat dissipator is formed from a material having excellent heat conducting properties, and the material is, for example, grease, a solder, a gap filler, or a compound. By thermally connecting the smoothing capacitor 12 to the cooler 14 with the heat dissipator therebetween, the smoothing capacitor 12 can be further efficiently cooled.

### Flat Surface Portion of Heat Generation Component

The at least one heat generation component thermally connected to the first cooling surface 14b has a flat surface portion formed on an opposite side to the first cooling surface 14b side parallelly to the first cooling surface 14b. In the present embodiment, the at least one heat generation component thermally connected to the first cooling surface 14b is the smoothing capacitor 12, and the smoothing capacitor 12 has a flat surface portion 15a formed parallelly to the first cooling surface 14b. In the present embodiment, the flat surface portion 15a is formed parallelly to the coolant flow path 14a. Neither the other heat generation components excluding the smoothing capacitor 12 as the at least one heat generation component thermally connected to the first cooling surface 14b nor the control board 11 is provided on the opposite side to the first cooling surface 14b side of the flat surface portion 15a. In a case where the power conversion device 1 has the housing 200, the flat surface portion 15a is a surface on a side in the mounting direction of the sub-assembly 100. In a case where the at least one heat generation component thermally connected to the first cooling surface 14b is a heat generation component other than the smoothing capacitor 12, the flat surface portion may be provided to the heat generation component thermally connected to the first cooling surface 14b other than the smoothing capacitor 12, e. g., the busbar assembly 13.

This configuring enables the power conversion device 1 shown in FIG. 1 to stand on its own by the flat surface portion 15a which is a base surface. Since the power conversion device 1 stands on its own, stability at the time of transportation by a conveyor is improved during transportation of the power conversion device 1, for example. Thus, work for mounting to the housing 200 can be easily performed during the transportation. Since work for mounting to the housing 200 can be easily performed, the productivity for the power conversion device 1 can be improved. In addition, since work for mounting to the housing 200 becomes easy, the quality of the power conversion device 1 during assembling can be advantageously ensured.

In addition, the shape of a turnover box and packaging work for the power conversion device 1 shown in FIG. 1 can be simplified, whereby the productivity for the power conversion device 1 can be improved. In a case where heat generation components are placed on surfaces on both sides of the cooler 14, it might be difficult to stabilize the product orientation during transportation with the power conversion device 1 being in the state shown in FIG. 1 owing to a difference in dimensions and shapes among the components. Therefore, provision of the flat surface portion 15a to the surface on the side in the mounting direction to the housing 200 as in the present disclosure directly leads to improvement of the productivity for the power conversion device 1.

### Modifications

Modifications of the power conversion device 1 will be described with reference to FIG. 4 and FIG. 5. FIG. 4 shows a modification of the power conversion device 1 shown in FIG. 1, and FIG. 5 shows a modification of the power conversion device 1 shown in FIG. 2. The cooler 14 has an opening provided in the first cooling surface or the second cooling surface and in communication with the coolant flow path 14a and a heat dissipation plate 25 covering the opening. In the present embodiment, an opening 14d is provided in the second cooling surface 14c. The heat dissipation plate 25 has, on a surface thereof on the coolant flow path 14a side, a plurality of heat dissipation fins 25a protruding to the coolant flow path 14a side. The heat dissipation plate 25 is formed from, for example, aluminum having excellent heat conducting properties.

The first cooling surface or the second cooling surface is formed on a surface of the heat dissipation plate 25 on an opposite side to the coolant flow path 14a side. The power module 10 is thermally connected to the first cooling surface or the second cooling surface on the heat dissipation plate 25. In the present embodiment, the second cooling surface 14c is formed on the surface of the heat dissipation plate 25 on the opposite side to the coolant flow path 14a side, and the power module 10 is thermally connected to the second cooling surface 14c on the heat dissipation plate 25. Sealing means between the heat dissipation plate 25 and the cooler 14 is, for example, a packing, friction stir welding (ESW), or electron beam welding.

This configuring enables increase in the heat dissipation area in the coolant flow path 14a. Since the heat dissipation area is increased, heat dissipation properties of the power module 10 can be improved. Since the heat dissipation properties of the power module 10 are improved, a power conversion device 1 having excellent cooling performance can be obtained. In addition, since the heat dissipation properties of the power module 10 are improved, the power conversion device 1 can be downsized.

### Manufacturing Method for Power Conversion Device 1

A manufacturing method for the power conversion device 1 will be described with reference to FIG. 6. The manufacturing method for the power conversion device 1 includes a member preparation step (S11), a sub-assembly formation step (S12), and a housing mounting step (S13). A manufacturing method including an inspection step (S12-1) will be described at the end. Hereinafter, each of the steps will be described.

The member preparation step is a step of preparing: the one or plurality of power modules 10, each of the power modules 10 having the one or plurality of semiconductor elements 10a and being connected to the power supply connection terminals 22 to be connected to the DC power supply; the control board 11 which controls switching operations of the semiconductor elements 10a; the smoothing capacitor 12 which smooths an input voltage to be inputted from the DC power supply to the power module 10; the busbar assembly 13 having the busbars 13a establishing electrical connection in at least two of intervals between the power supply connection terminals 22, the power module 10, and the smoothing capacitor 12; the cooler 14 having the first cooling surface 14b, the second cooling surface 14c on the opposite side to the first cooling surface 14b, and the coolant flow path 14a which is formed in the cooler 14; and the housing 200 formed in the shape of a tube with a bottom.

The sub-assembly formation step is a step of thermally connecting at least one of the power module 10, the smoothing capacitor 12, and the busbar assembly 13 to the first cooling surface 14b and thermally connecting at least one of the power module 10, the smoothing capacitor 12, and the busbar assembly 13 to the second cooling surface 14c to form a sub-assembly of the power conversion device 1 from the power module 10, the control board 11, the smoothing capacitor 12, the busbar assembly 13, and the cooler 14. The sub-assembly of the power conversion device 1 formed in this step has, for example, the configuration of the power conversion device 1 shown in FIG. 1. In FIG. 1, the smoothing capacitor 12 is thermally connected to the first cooling surface 14b, and the power module 10 is thermally connected to the second cooling surface 14c. The busbar assembly 13 is disposed on the opposite side to the cooler 14 side of the power module 10. The control board 11 is disposed on the opposite side to the power module 10 side of the busbar assembly 13.

The housing mounting step is a step of accommodating the sub-assembly in the housing 200. The power conversion device 1 formed in this step has, for example, the configuration of the power conversion device 1 shown in FIG. 2. The sub-assembly 100 is fixed to the housing 200 by using, for example, the connection boss (not shown) provided to the cooler 14. The first cooling surface 14b and the second cooling surface 14c are provided on both sides of the coolant flow path 14a parallelly to each other. The first cooling surface 14b and the second cooling surface 14c are orthogonal to the direction of the normal to the inner surface of the bottom wall 200a of the housing 200. The mounting direction of the sub-assembly 100 to the housing 200 is the direction orthogonal to the first cooling surface 14b and the second cooling surface 14c.

By thus manufacturing the power conversion device 1, the mounting direction of the sub-assembly 100 to the housing 200 becomes the direction orthogonal to the first cooling surface 14b and the second cooling surface 14c, whereby the sub-assembly 100 can be easily mounted to the housing 200. Since the sub-assembly 100 is easily mounted to the housing 200, the productivity for the power conversion device 1 can be improved. The sub-assembly 100 may have a power conversion function and a cooling function, and the manufacturing method for the power conversion device 1 may include an inspection step of inspecting the power conversion function and the cooling function, the inspection step preceding the housing mounting step. By inspecting the power conversion function and the cooling function before the housing mounting step, the productivity for the power conversion device 1 can be improved.

As described above, the power conversion device 1 according to embodiment 1 includes: the one or plurality of power modules 10; the control board 11; the smoothing capacitor 12 as the at least one electrical component; the busbar assembly 13 having the busbars 23; and the cooler 14 having the first cooling surface 14b, the second cooling surface 14c, and the coolant flow path 14a which is formed in the cooler 14. Each power module 10, the smoothing capacitor 12, and the busbar assembly 13 are heat generation components. The first cooling surface 14b and the second cooling surface 14c are provided on both sides of the coolant flow path 14a parallelly to each other. The power module 10 as one of the heat generation components is thermally connected to the first cooling surface 14b. The smoothing capacitor 12 as one of the heat generation components is thermally connected to the second cooling surface 14c. Consequently, it is possible to thermally connect, in addition to the power module 10 as one of the heat generation components, the smoothing capacitor 12 as another one of the heat generation components to the cooler 14 without upsizing the cooler 14. Since both of the two heat generation components are thermally connected to the cooler 14, the heat dissipation properties of the two heat generation components are improved, whereby a power conversion device 1 having excellent cooling performance can be obtained. In addition, the power conversion device 1 shown in FIG. 1 has a power conversion function and a cooling function and enables inspection of the power conversion function and the cooling function. Thus, the power conversion device 1 is completed as an integrated unit that can exhibit main functions (e.g., the inverter function and the cooling function) required for the power conversion device 1 and enables inspection of the main functions without being incorporated into a housing or the like. Consequently, the productivity for the power conversion device 1 can be improved.

A case is assumed where: the power conversion device 1 includes the housing 200; the heat generation components, the control board 11, and the cooler 14 composing the sub-assembly 100 are accommodated in the housing 200; and the first cooling surface 14b and the second cooling surface 14c are orthogonal to the direction of the normal to the opposed surface of the housing 200 opposed to the first cooling surface 14b or the second cooling surface 14c. In this case, the mounting direction of the sub-assembly 100 to the housing 200 becomes the direction orthogonal to the first cooling surface 14b and the second cooling surface 14c, whereby the sub-assembly 100 can be easily mounted to the housing 200. Since the sub-assembly 100 is easily mounted to the housing 200, the productivity for the power conversion device 1 can be improved. In a case where the housing 200 is formed in the shape of a tube with a bottom, the housing 200 can be easily manufactured.

A case is assumed where: the smoothing capacitor 12 as the at least one heat generation component thermally connected to the first cooling surface 14b has the flat surface portion 15a formed on the opposite side to the first cooling surface 14b side parallelly to the first cooling surface 14b; and neither the other heat generation components excluding the smoothing capacitor 12 as the at least one heat generation component thermally connected to the first cooling surface 14b nor the control board 11 is provided on the opposite side to the first cooling surface 14b side of the flat surface portion 15a. In this case, the power conversion device 1 shown in FIG. 1 is allowed to stand on its own by the flat surface portion 15a which is a base surface. Since the power conversion device 1 stands on its own, stability at the time of transportation by a conveyor is improved during transportation of the power conversion device 1, for example. Thus, work for mounting to the housing 200 can be easily performed during the transportation. Since work for mounting to the housing 200 can be easily performed, the productivity for the power conversion device 1 can be improved. In addition, since work for mounting to the housing 200 becomes easy, the quality of the power conversion device 1 during assembling can be advantageously ensured.

In a case where the smoothing capacitor 12 as a heat generation component is thermally connected to the first cooling surface 14b or the second cooling surface 14c, the smoothing capacitor 12 having a large heat generation amount can be thermally connected to the cooler 14. Since the smoothing capacitor 12 is thermally connected to the cooler 14, the heat dissipation properties of the smoothing capacitor 12 are improved, whereby a power conversion device 1 having excellent cooling performance can be obtained. In addition, since the heat dissipation properties of the smoothing capacitor 12 are improved, the capacitor elements 12b of the smoothing capacitor 12 can be downsized. Since the capacitor elements 12b are downsized, the smoothing capacitor 12 is downsized, whereby the power conversion device 1 can be downsized.

A case is assumed where: the cooler 14 has the opening provided in the first cooling surface or the second cooling surface and in communication with the coolant flow path 14a and the heat dissipation plate 25 covering the opening; the heat dissipation plate 25 has, on the surface thereof on the coolant flow path 14a side, the plurality of heat dissipation fins 25a protruding to the coolant flow path 14a side; the first cooling surface or the second cooling surface is formed on the surface of the heat dissipation plate 25 on the opposite side to the coolant flow path 14a side; and the power module 10 is thermally connected to the first cooling surface or the second cooling surface on the heat dissipation plate 25. In this case, the heat dissipation area in the coolant flow path 14a can be increased, whereby the heat dissipation properties of the power module 10 can be improved. Since the heat dissipation properties of the power module 10 are improved, a power conversion device 1 having excellent cooling performance can be obtained.

The manufacturing method for the power conversion device 1 includes: the member preparation step of preparing the power module 10, the control board 11, the smoothing capacitor 12, the busbar assembly 13, the cooler 14, and the housing 200; the sub-assembly formation step of thermally connecting at least one of the power module 10, the smoothing capacitor 12, and the busbar assembly 13 to the first cooling surface 14b and thermally connecting at least one of the power module 10, the smoothing capacitor 12, and the busbar assembly 13 to the second cooling surface 14c to form a sub-assembly of the power conversion device 1 from the power module 10, the control board 11, the smoothing capacitor 12, the busbar assembly 13, and the cooler 14; and the housing mounting step of accommodating the sub-assembly in the housing 200. The first cooling surface 14b and the second cooling surface 14c are provided on both sides of the coolant flow path 14a parallelly to each other. The first cooling surface 14b and the second cooling surface 14c are orthogonal to the direction of the normal to the inner surface of the bottom wall 200a of the housing 200. The mounting direction of the sub-assembly to the housing 200 is the direction orthogonal to the first cooling surface 14b and the second cooling surface 14c. Consequently, the sub-assembly can be easily mounted to the housing 200. Since the sub-assembly is easily mounted to the housing 200, the productivity for the power conversion device 1 can be improved. In addition, in a case where the sub-assembly 100 has a power conversion function and a cooling function, and the manufacturing method includes an inspection step of inspecting the power conversion function and the cooling function, the inspection step preceding the housing mounting step, the power conversion function and the cooling function can be inspected before the housing mounting step, whereby the productivity for the power conversion device 1 can be improved.

### Embodiment 2

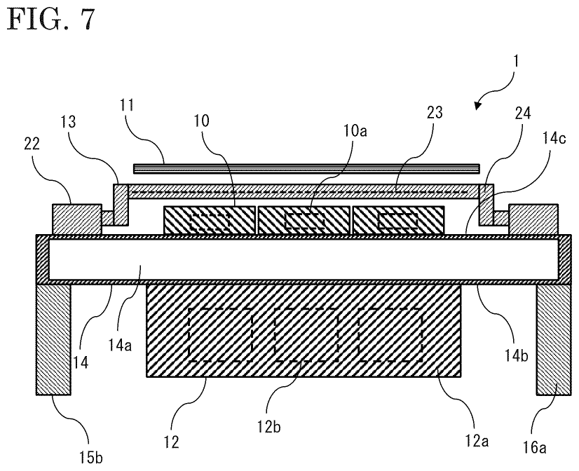

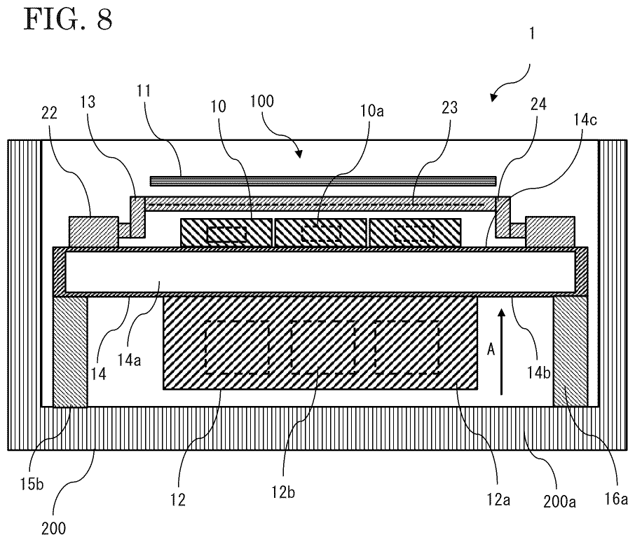

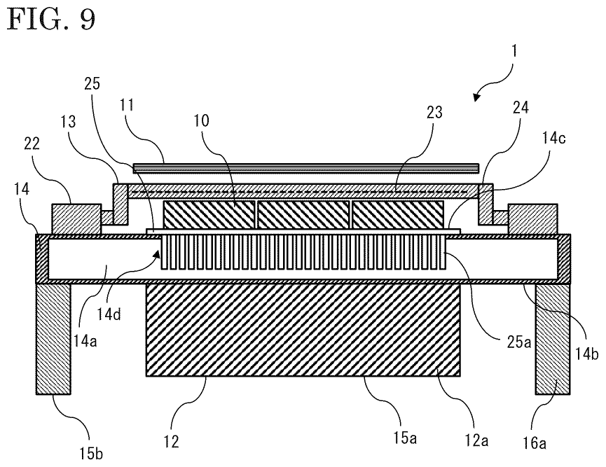

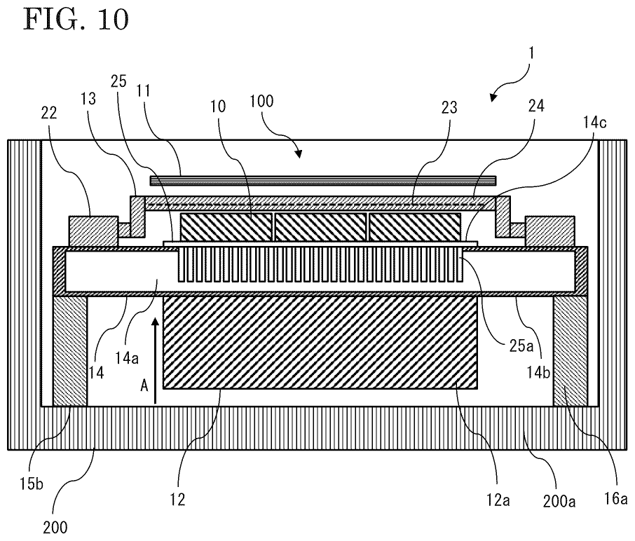

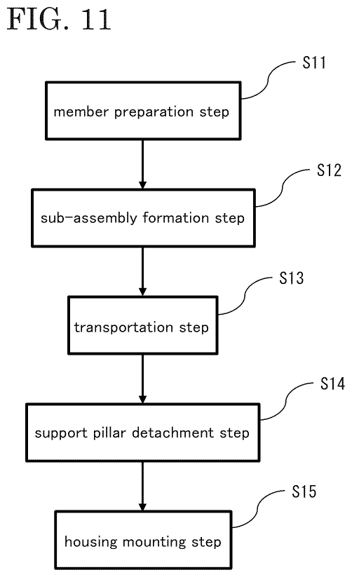

A power conversion device 1 according to embodiment 2 will be described. FIG. 7 is a side view schematically showing the power conversion device 1 according to embodiment 2, with the side wall of the cooler 14 being partially removed. FIG. 8 is a side view schematically showing the power conversion device 1, with the peripheral wall of the housing 200 being partially removed. FIG. 9 is a side view schematically showing another power conversion device 1 according to embodiment 2, with the side wall of the cooler 14 being partially removed. FIG. 10 is a side view schematically showing the other power conversion device 1, with the peripheral wall of the housing 200 being partially removed. FIG. 11 shows a manufacturing process for the power conversion device 1. The power conversion device 1 according to embodiment 2 includes a plurality of support pillars 16a in addition to the constituents in embodiment 1.

As shown in FIG. 7, the power conversion device 1 includes a plurality of support pillars 16a located on the first cooling surface 14b side and protruding in a direction away from the first cooling surface 14b. In the present embodiment, the plurality of support pillars 16a are disposed inward of an outer periphery of the first cooling surface 14b and are fixed to the first cooling surface 14b. Also, in the present embodiment, the first cooling surface 14b is formed in a rectangular shape, and thus the support pillars 16a, the number of which is four, are disposed at the respective four corners of the first cooling surface 14b. The arrangement, the fixation locations, and the number of the plurality of support pillars 16a are not limited thereto. The support pillars 16a are formed from, for example, iron, an aluminum alloy, or a resin material. The fixation of the support pillars 16a is achieved through, for example, fastening with screws, fitting, adhesion, or welding. The support pillars 16a and the cooler 14 may be integrated with each other.

Each of the plurality of support pillars 16a has a support pillar flat surface portion 15b formed at an end portion thereof on an opposite side to the first cooling surface 14b side parallelly to the first cooling surface 14b. The support pillar flat surface portions 15b are provided on a same plane parallel to the first cooling surface 14b, and neither the heat generation components nor the control board 11 is provided on the opposite side to the first cooling surface 14b side of each of the support pillar flat surface portions 15b.

This configuring enables the power conversion device 1 shown in FIG. 7 to stand on its own by the support pillar flat surface portions 15b which are base surfaces. Since the power conversion device 1 stands on its own, stability at the time of transportation by a conveyor is improved during transportation of the power conversion device 1, for example. Thus, work for mounting to the housing 200 can be easily performed during the transportation. Since work for mounting to the housing 200 can be easily performed, the productivity for the power conversion device 1 can be improved. In addition, since work for mounting to the housing 200 becomes easy, the quality of the power conversion device 1 during assembling can be advantageously ensured. In addition, in this configuration, no flat surface portions are formed on the electrical components. Thus, the electrical components do not have any portions to be used for transportation, whereby damage to the electrical components during transportation can be suppressed.

A configuration in which the power conversion device 1 shown in FIG. 7 is accommodated in the housing 200 will be described with reference to FIG. 8. The power conversion device 1 shown in FIG. 7 is referred to as “sub-assembly 100” in FIG. 8. The power conversion device 1 includes the housing 200. The heat generation components, the control board 11, the cooler 14, and the support pillars 16a are accommodated in the housing 200. In the present embodiment, the heat generation components are each of the power modules 10, the smoothing capacitor 12, and the busbar assembly 13. The first cooling surface 14b and the second cooling surface 14c are orthogonal to the direction of the normal to the opposed surface of the housing 200 opposed to the first cooling surface 14b or the second cooling surface 14c. In the present embodiment, the housing 200 is formed in the shape of a tube with a bottom, and the opposed surface of the housing 200 is the inner surface of the bottom wall 200a of the housing 200. The shape of the housing 200 is not limited to the shape of a tube with a bottom. However, in the case where the housing 200 has the shape of a tube with a bottom, the housing 200 can be easily manufactured. The direction of the normal to the. inner surface of the bottom wall 200a is the direction indicated by the arrow A in FIG. 8. The support pillar flat surface portions 15b are in contact with the inner surface of the bottom wall 200a of the housing 200. The sub-assembly 100 is fixed to the housing 200 by the support pillar flat surface portions 15b.

This configuring causes the mounting direction of the sub-assembly 100 to the housing 200 to be the direction orthogonal to the first cooling surface 14b and the second cooling surface 14c, whereby the sub-assembly 100 can be easily mounted to the housing 200. Since the sub-assembly 100 is easily mounted to the housing 200, the productivity for the power conversion device 1 can be improved. In addition, since the sub-assembly 100 can be fixed to the housing 200 by the support pillar flat surface portions 15b, the sub-assembly 100 can be easily fixed to the housing 200 without providing any other fixation members.

In the present embodiment, the plurality of support pillars 16a are detachably provided. This configuring enables the support pillars 16a to be detached from the sub-assembly 100 when the sub-assembly 100 is mounted to the housing 200. The detachment of the support pillars 16a enables decrease in the weight of the power conversion device 1 without impairing the stability of the sub-assembly 100 at the time of transportation by a conveyor.

A manufacturing method for the detachable support pillars 16a will be described. In a case where the support pillars 16a are formed to be detachable by using screws, screw hole machining is performed on body portions of support pillars 16a obtained through extrusion or die casting. The screw holes provided in the body portions of the support pillars 16a are used to fasten the support pillars 16a to, for example, the cooler 14 or the busbar assembly 13. In a case where the support pillars 16a are formed from a resin, nuts are insert-molded into the support pillars 16a formed from the resin, whereby the detachable support pillars 16a can be manufactured.

The heights and the shapes of the support pillar flat surface portions 15b which are base surfaces vary depending on the shape of the product or the manner of transportation. Therefore, dimensional restrictions are not particularly imposed on the support pillars 16a, except that: the support pillar flat surface portions 15b are provided on the same plane parallel to the first cooling surface 14b; and neither the heat generation components nor the control board 11 is provided on the opposite side to the first cooling surface 14b side of each of the support pillar flat surface portions 15b.

### Modifications

Modifications of the power conversion device 1 will be described with reference to FIG. 9 and FIG. 10. FIG. 9 shows a modification of the power conversion device 1 shown in FIG. 7, and FIG. 10 shows a modification of the power conversion device 1 shown in FIG. 8. The cooler 14 has the opening provided in the first cooling surface or the second cooling surface and in communication with the coolant flow path 14a and the heat dissipation plate 25 covering the opening. In the present embodiment, the opening 14d is provided in the second cooling surface 14c. The heat dissipation plate 25 has, on the surface thereof on the coolant flow path 14a side, the plurality of heat dissipation fins 25a protruding to the coolant flow path 14a side. The heat dissipation plate 25 is formed from, for example, aluminum having excellent heat conducting properties.

The first cooling surface or the second cooling surface is formed on the surface of the heat dissipation plate 25 on the opposite side to the coolant flow path 14a side. The power module 10 is thermally connected to the first cooling surface or the second cooling surface on the heat dissipation plate 25. In the present embodiment, the second cooling surface 14c is formed on the surface of the heat dissipation plate 25 on the opposite side to the coolant flow path 14a side, and the power module 10 is thermally connected to the second cooling surface 14c on the heat dissipation plate 25.

This configuring enables increase in the heat dissipation area in the coolant flow path 14a. Since the heat dissipation area is increased, the heat dissipation properties of the power module 10 can be improved. Since the heat dissipation properties of the power module 10 are improved, a power conversion device 1 having excellent cooling performance can be obtained. In addition, since the heat dissipation properties of the power module 10 are improved, the power conversion device 1 can be downsized.

### Manufacturing Method for Power Conversion Device 1

A manufacturing method for the power conversion device 1 will be described with reference to FIG. 11. The manufacturing method for the power conversion device 1 includes a member preparation step (S11), a sub-assembly formation step (S12), a transportation step (S13), a support pillar detachment step (S14), and a housing mounting step (S15). Hereinafter, each of the steps will be described.

The member preparation step is a step of preparing: the one or plurality of power modules 10, each of the power modules 10 having the one or plurality of semiconductor elements 10a and being connected to the power supply connection terminals 22 to be connected to the DC power supply; the control board 11 which controls switching operations of the semiconductor elements 10a; the smoothing capacitor 12 which smooths an input voltage to be inputted from the DC power supply to the power module 10; the busbar assembly 13 having the busbars 13a establishing electrical connection in at least two of the intervals between the power supply connection terminals 22, the power module 10, and the smoothing capacitor 12; the cooler 14 having the first cooling surface 14b, the second cooling surface 14c on the opposite side to the first cooling surface 14b, and the coolant flow path 14a which is formed in the cooler 14; the plurality of detachably formed support pillars 16a; and the housing 200 formed in the shape of a tube with a bottom.

The sub-assembly formation step is a step of thermally connecting at least one of the power module 10, the smoothing capacitor 12, and the busbar assembly 13 to the first cooling surface 14b, thermally connecting at least one of the power module 10, the smoothing capacitor 12, and the busbar assembly 13 to the second cooling surface 14c, and attaching the plurality of support pillars 16a to the first cooling surface 14b with the support pillars 16a protruding in a direction away from the first cooling surface 14b to form a sub-assembly of the power conversion device 1 from the power module 10, the control board 11, the smoothing capacitor 12, the busbar assembly 13, the cooler 14, and the plurality of support pillars 16a. The sub-assembly of the power conversion device 1 formed in this step has, for example, the configuration of the power conversion device 1 shown in FIG. 7. In FIG. 7, the smoothing capacitor 12 is thermally connected to the first cooling surface 14b, and the power module 10 is thermally connected to the second cooling surface 14c. The busbar assembly 13 is disposed on the opposite side to the cooler 14 side of the power module 10. The control board 11 is disposed on the opposite side to the power module 10 side of the busbar assembly 13. The plurality of support pillars 16a are fastened to the first cooling surface 14b by using, for example, screws.

The transportation step is a step of transporting the sub-assembly to a disposition location of the housing 200 in a state where the support pillar flat surface portion 15b provided to an end portion on an opposite side to the first cooling surface 14b side of each of the plurality of support pillars 16a has been brought into contact with a support surface so that the sub-assembly has been caused to stand. In a case where the sub-assembly is transported by a conveyor, the support surface is provided to the conveyor.

The support pillar detachment step is a step of detaching each of the plurality of support pillars 16a from the sub-assembly. In a case where the support pillars 16a are fastened to the first cooling surface 14b by using screws, the support pillar detachment step includes detaching the screws. The housing mounting step is a step of accommodating, in the housing 200, the sub-assembly from which the plurality of support pillars 16a have been detached. The power conversion device 1 formed in this step has, for example, the configuration of the power conversion device 1 shown in FIG. 2.

After the sub-assembly formation step is performed, the support pillar flat surface portions 15b in the sub-assembly are provided on the same plane parallel to the first cooling surface 14b. After the sub-assembly formation step is performed, none of the power module 10, the smoothing capacitor 12, the busbar assembly 13, and the control board 11 is provided on the opposite side to the first cooling surface 14b side of each of the support pillar flat surface portions 15b in the sub-assembly. Therefore, the power conversion device 1 is allowed to stand on its own by the support pillar flat surface portions 15b which are base surfaces. Since the power conversion device 1 stands on its own, stability at the time of transportation by a conveyor is improved during transportation of the power conversion device 1, for example. Thus, work for mounting to the housing 200 can be easily performed during the transportation.

The sub-assembly is fixed to the housing 200 by using, for example, the connection boss (not shown) provided to the cooler 14. The first cooling surface 14b and the second cooling surface 14c are provided on both sides of the coolant flow path 14a parallelly to each other. The first cooling surface 14b and the second cooling surface 14c are orthogonal to the direction of the normal to the inner surface of the bottom wall 200a of the housing 200. The mounting direction of the sub-assembly to the housing 200 is the direction orthogonal to the first cooling surface 14b and the second cooling surface 14c.

By thus manufacturing the power conversion device 1, the detachment of the support pillars 16a from the sub-assembly at the time of mounting the sub-assembly to the housing 200 enables decrease in the weight of the power conversion device 1 without impairing the stability of the sub-assembly at the time of transportation by a conveyor.

Since the mounting direction of the sub-assembly to the housing 200 is the direction orthogonal to the first cooling surface 14b and the second cooling surface 14c, the sub-assembly can be easily mounted to the housing 200. Since the sub-assembly is easily mounted to the housing 200, the productivity for the power conversion device 1 can be improved.

### Embodiment 3

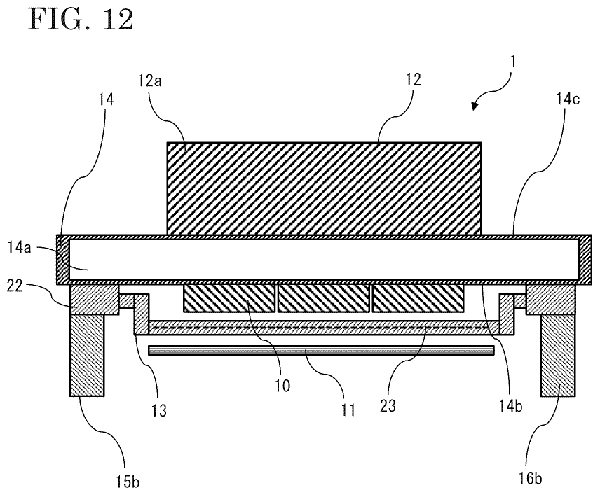

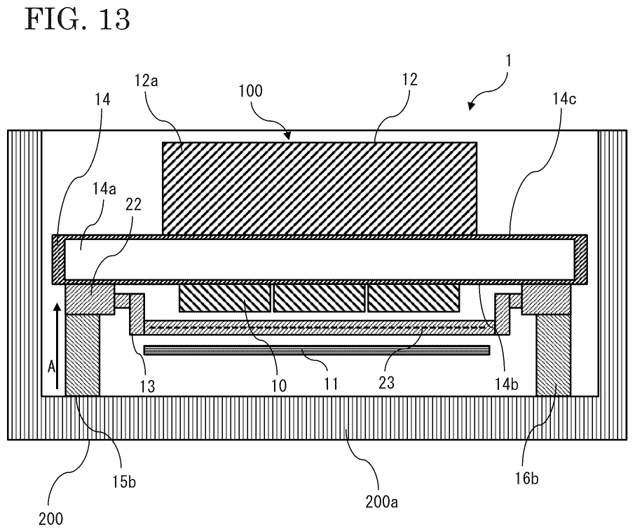

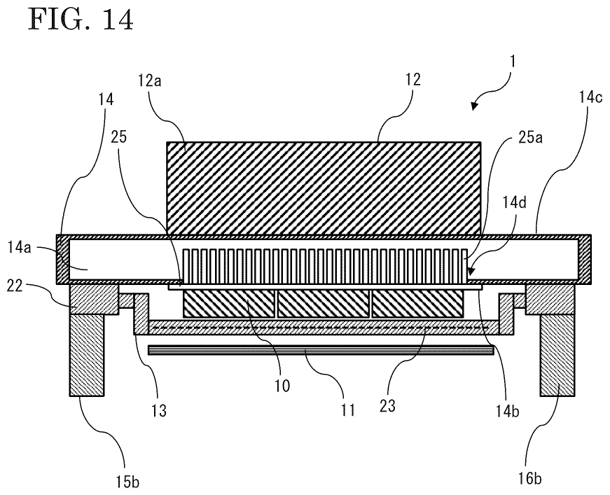

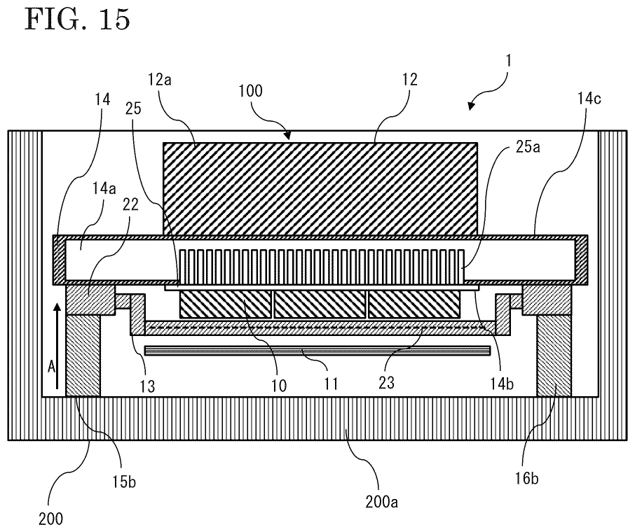

A power conversion device 1 according to embodiment 3 will be described. FIG. 12 is a side view schematically showing the power conversion device 1 according to embodiment 3, with the side wall of the cooler 14 being partially removed. FIG. 13 is a side view schematically showing the power conversion device 1, with the peripheral wall of the housing 200 being partially removed. FIG. 14 is a side view schematically showing another power conversion device 1 according to embodiment 3, with the side wall of the cooler 14 being partially removed. FIG. 15 is a side view schematically showing the other power conversion device 1, with the peripheral wall of the housing 200 being partially removed. The power conversion device 1 according to embodiment 3 has a configuration in which the arrangement of the heat generation components and the control board 11 differs from the arrangement in embodiment 1.

As shown in FIG. 12, in the present embodiment, each of the power modules 10 as a heat generation component is thermally connected to the first cooling surface 14b, and the smoothing capacitor 12 as a heat generation component is thermally connected to the second cooling surface 14c. Even when the arrangement of the heat generation components is the reverse of the arrangement in embodiment 1 in this manner, both of the two heat generation components are thermally connected to the cooler 14 without upsizing the cooler 14. Consequently, the heat dissipation properties of the two heat generation components are improved, whereby a power conversion device 1 having excellent cooling performance can be obtained. In addition, since the heat dissipation properties of the two heat generation components are improved, both of the two heat generation components can be downsized. Since both of the two heat generation components are downsized, the power conversion device 1 can be downsized.

In the present embodiment, the busbar assembly 13 is disposed on the opposite side to the cooler 14 side of the power module 10. The control board 11 is disposed on the opposite side to the power module 10 side of the busbar assembly 13. As shown in FIG. 13, in the present embodiment, the power module 10, the busbar assembly 13, and the control board 11 are disposed on the side in the mounting direction to the housing 200. The arrangement of the heat generation components and the control board 11 in the sub-assembly 100 described in the present embodiment is the reverse of the arrangement in the sub-assembly 100 described in embodiment 1.

As shown in FIG. 12, the power conversion device 1 includes a plurality of support pillars 16b located on the first cooling surface 14b side and protruding in a direction away from the first cooling surface 14b. In the present embodiment, the plurality of support pillars 16b are disposed inward of the outer periphery of the first cooling surface 14b and are fixed to the busbar assembly 13. The arrangement. and the fixation locations of the plurality of support pillars 16b are not limited thereto.

Each of the plurality of support pillars 16b has a support pillar flat surface portion 15b formed at an end portion thereof on the opposite side to the first cooling surface 14b side parallelly to the first cooling surface 14b. The support pillar flat surface portions 15b are provided on the same plane parallel to the first cooling surface 14b, and neither the heat generation components nor the control board 11 is provided on the opposite side to the first cooling surface 14b side of each of the support pillar flat surface portions 15b. Therefore, the power conversion device 1 shown in FIG. 12 is allowed to stand on its own by the support pillar flat surface portions 15b which are base surfaces. Since the power conversion device 1 stands on its own, stability at the time of transportation by a conveyor is improved during transportation of the power conversion device 1, for example. Thus, work for mounting to the housing 200 can be easily performed during the transportation. Since work for mounting to the housing 200 can be easily performed, the productivity for the power conversion device 1 can be improved.

The support pillars 16b are formed from, for example, iron, an aluminum alloy, or a resin material. The support pillars 16b are fixed to the busbar assembly 13 through, for example, fastening with screws, fitting, adhesion, or welding. A configuration in which the support pillars 16b and the busbar assembly 13 are integrated with each other may be employed. Alternatively, the support pillars 16b may be fixed to the first cooling surface 14b.

The plurality of support pillars 16b may be detachably provided. This configuring enables the support pillars 16b to be detached from the sub-assembly 100 when the sub-assembly 100 is mounted to the housing 200. The detachment of the support pillars 16b enables decrease in the weight of the power conversion device 1 without impairing the stability of the sub-assembly 100 at the time of transportation by a conveyor.

The heights and the shapes of the support pillar flat surface portions 15b which are base surfaces vary depending on the shape of the product or the manner of transportation. Therefore, dimensional restrictions are not particularly imposed on the support pillars 16b, except that: the support pillar flat surface portions 15b are provided on the same plane parallel to the first cooling surface 14b; and neither the heat generation components nor the control board 11 is provided on the opposite side to the first cooling surface 14b side of each of the support pillar flat surface portions 15b.

### Modifications

Modifications of the power conversion device 1 will be described with reference to FIG. 14 and FIG. 15. FIG. 14 shows a modification of the power conversion device 1 shown in FIG. 12, and FIG. 15 shows a modification of the power conversion device 1 shown in FIG. 13. The cooler 14 has the opening provided in the first cooling surface or the second cooling surface and in communication with the coolant flow path 14a and the heat dissipation plate 25 covering the opening. In the present embodiment, the opening 14d is provided in the first cooling surface 14b. The heat dissipation plate 25 has, on the surface thereof on the coolant flow path 14a side, the plurality of heat dissipation fins 25a protruding to the coolant flow path 14a side. The heat dissipation plate 25 is formed from, for example, aluminum having excellent heat conducting properties.

The first cooling surface or the second cooling surface is formed on the surface of the heat dissipation plate 25 on the opposite side to the coolant flow path 14a side. The power module 10 is thermally connected to the first cooling surface or the second cooling surface on the heat dissipation plate 25. In the present embodiment, the first cooling surface 14b is formed on the surface of the heat dissipation plate 25 on the opposite side to the coolant flow path 14a side, and the power module 10 is thermally connected to the first cooling surface 14b on the heat dissipation plate 25.

This configuring enables increase in the heat dissipation area in the coolant flow path 14a. Since the heat dissipation area is increased, the heat dissipation properties of the power module 10 can be improved. Since the heat dissipation properties of the power module 10 are improved, a power conversion device 1 having excellent cooling performance can be obtained. In addition, since the heat dissipation properties of the power module 10 are improved, the power conversion device 1 can be downsized.

### Embodiment 4

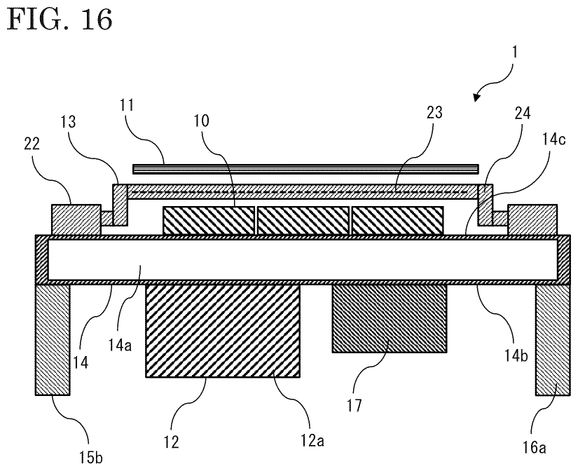

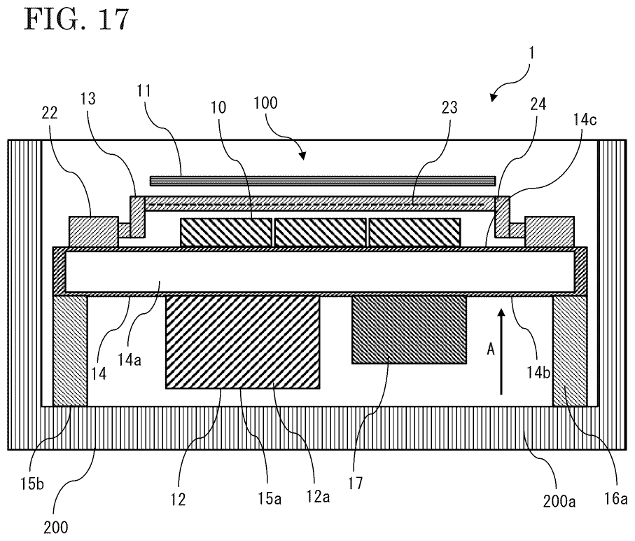

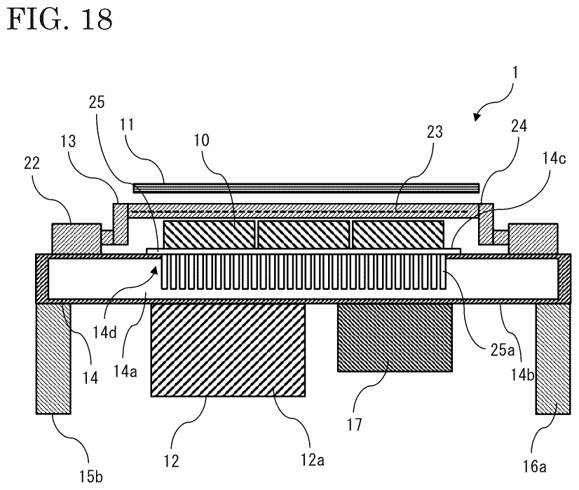

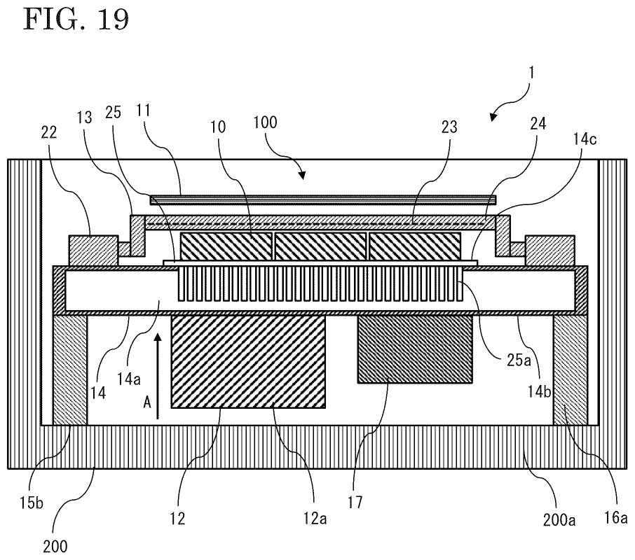

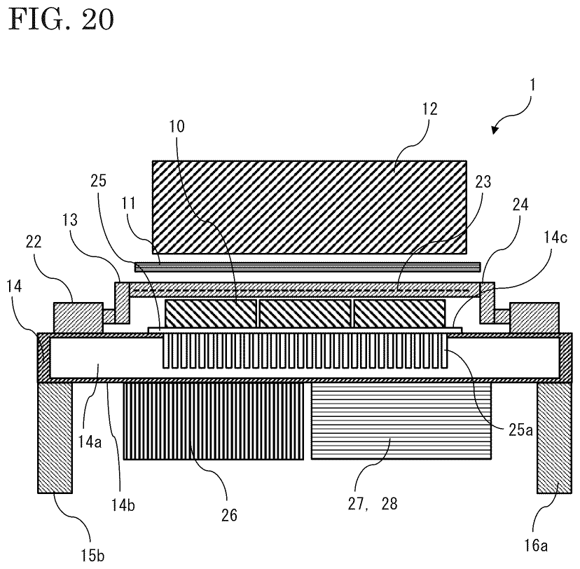

A power conversion device 1 according to embodiment 4 will be described. FIG. 16 is a side view schematically showing the power conversion device 1 according to embodiment 4, with the side wall of the cooler 14 being partially removed. FIG. 17 is a side view schematically showing the power conversion device 1, with the peripheral wall of the housing 200 being partially removed. FIG. 18 is a side view schematically showing another power conversion device 1 according to embodiment 4, with the side wall of the cooler 14 being partially removed. FIG. 19 is a side view schematically showing the other power conversion device 1, with the peripheral wall of the housing 200 being partially removed. FIG. 20 is a side view schematically showing still another power conversion device 1 according to embodiment 4, with the side wall of the cooler 14 being partially removed. The power conversion device 1 according to embodiment 4 has a configuration in which a heat generation component has been added to the constituents in embodiment 1.

As shown in FIG. 16, in the present embodiment, the power conversion device 1 includes a reactor 17 that is an electrical component and that is a heat generation component. The reactor 17 forms a portion of a boosting circuit for stepping up an input voltage to each of the power modules 10. The reactor 17 is an electromagnetic component for converting electric energy into magnetic energy, and accumulating and discharging the energy. Through the reactor 17, a high current of up to several hundreds of A flows, and thus the reactor 17 is a heat generation component having a large heat generation amount.

The reactor 17 is connected to the busbars 13a in the busbar assembly 13. The connection between the reactor 17 and the busbars 13a is achieved through, for example, fastening with screws or TIG welding. The reactor 17 is electrically connected to the power module 10 and the smoothing capacitor 12 via the busbars 13a.

The reactor 17 as a heat generation component is thermally connected to the first cooling surface 14b. On the first cooling surface 14b, the smoothing capacitor 12 and the reactor 17 are disposed side-by-side. Heat generated in the reactor 17 is transmitted via the cooler 14 to the coolant flowing through the coolant flow path 14a. Although the reactor 17 is provided to the first cooling surface 14b in the present embodiment, no limitation thereto is made, and the reactor 17 may be thermally connected to the second cooling surface 14c.

By thermally connecting a plurality of heat generation components to one or both of the first cooling surface 14b and the second cooling surface 14c, the heat dissipation properties of the plurality of heat generation components are further improved, whereby a power conversion device 1 having further excellent cooling performance can be obtained. In addition, since a plurality of heat generation components are provided side-by-side on one of the cooling surfaces, the height of the power conversion device 1 can be decreased. The number of the heat generation components to be thermally connected to the cooling surface(s) is not limited thereto, and a larger number of heat generation components may be thermally connected to the cooling surface(s).

As shown in FIG. 17, in the present embodiment, the smoothing capacitor 12 and the reactor 17 are arranged on the side in the mounting direction to the housing 200. The heights of the smoothing capacitor 12 and the reactor 17 in the mounting direction differ from each other. Therefore, it is difficult for the sub-assembly 100 to stably stand on its own by the flat surface portion 15a of the smoothing capacitor 12. However, in the present embodiment, since the support pillars 16 are provided in this configuration, the sub-assembly 100 can be transported to the housing 200 in a state of standing on its own by the support pillars 16a.

### Modification 1

Modifications of the power conversion device 1 will be described with reference to FIG. 18 and FIG. 19. FIG. 18 shows a modification of the power conversion device 1 shown in FIG. 16, and FIG. 19 shows a modification of the power conversion device 1 shown in FIG. 17. The cooler 14 has the opening provided in the first cooling surface or the second cooling surface and in communication with the coolant flow path 14a and the heat dissipation plate 25 covering the opening. In the present embodiment, the opening 14d is provided in the second cooling surface 14c. The heat dissipation plate 25 has, on the surface thereof on the coolant flow path 14a side, the plurality of heat dissipation fins 25a protruding to the coolant flow path 14a side. The heat dissipation plate 25 is formed from, for example, aluminum having excellent heat conducting properties.

The first cooling surface or the second cooling surface is formed on the surface of the heat dissipation plate 25 on the opposite side to the coolant flow path 14a side. The power module 10 is thermally connected to the first cooling surface or the second cooling surface on the heat dissipation plate 25. In the present embodiment, the second cooling surface 14c is formed on the surface of the heat dissipation plate 25 on the opposite side to the coolant flow path 14a side, and the power module 10 is thermally connected to the second cooling surface 14c on the heat dissipation plate 25.

This configuring enables increase in the heat dissipation area in the coolant flow path 14a. Since the heat dissipation area is increased, the heat dissipation properties of the power module 10 can be improved. Since the heat dissipation properties of the power module 10 are improved, a power conversion device 1 having excellent cooling performance can be obtained. In addition, since the heat dissipation properties of the power module 10 are improved, the power conversion device 1 can be downsized.

### Modification 2

Anther modification of the power conversion device 1 will be described with reference to FIG. 20. In modification 2, the power conversion device 1 includes a boost converter unit 26 and a buck converter unit 27 which are electrical components and which are heat generation components. In modification 2, the boost converter unit 26 and the buck converter unit 27 are thermally connected to the first cooling surface 14b, and the power module 10 is thermally connected to the second cooling surface 14c. The boost converter unit 26 steps up an input voltage from the DC power supply 21 including the reactor 17. The buck converter unit 27 steps down the input voltage from the DC power supply 21. The smoothing capacitor 12 is disposed on an opposite side to the busbar assembly 13 side of the control board 11. The smoothing capacitor 12 is fixed to the busbar assembly 13 or the cooler 14 by, for example, providing a fastening boss or a fastening leg portion to the smoothing capacitor 12.

The heat generation components to be thermally connected to the cooling surfaces are not limited thereto, and a transmission control unit (TCU) 28 may be provided instead of the boost converter unit 26 or the buck converter unit 27. The transmission control unit 28 controls a transmission actuator. By thermally connecting a plurality of heat generation components to one of the cooling surfaces, the heat dissipation properties of the plurality of heat generation components are further improved, whereby a power conversion device 1 having further excellent cooling performance can be obtained.

### Embodiment 5

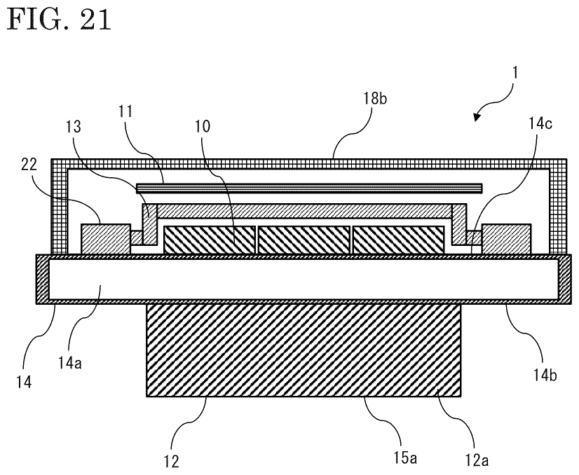

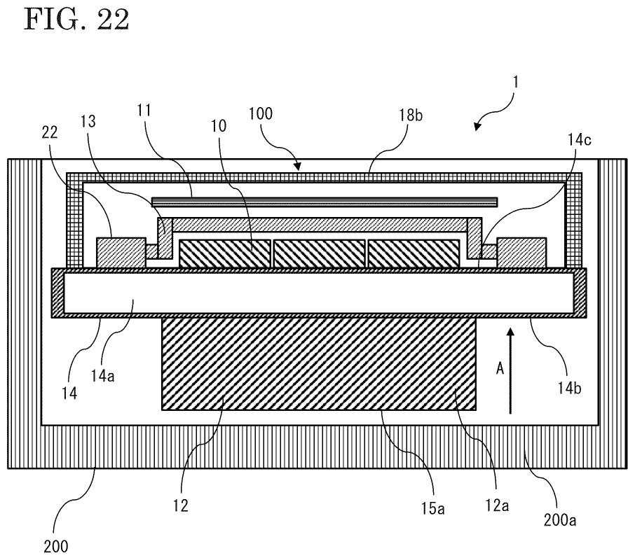

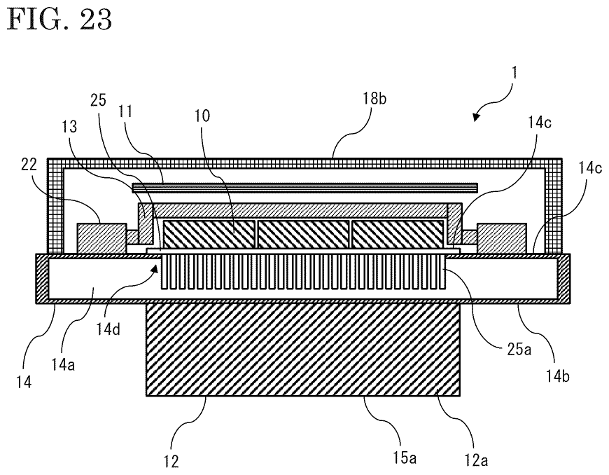

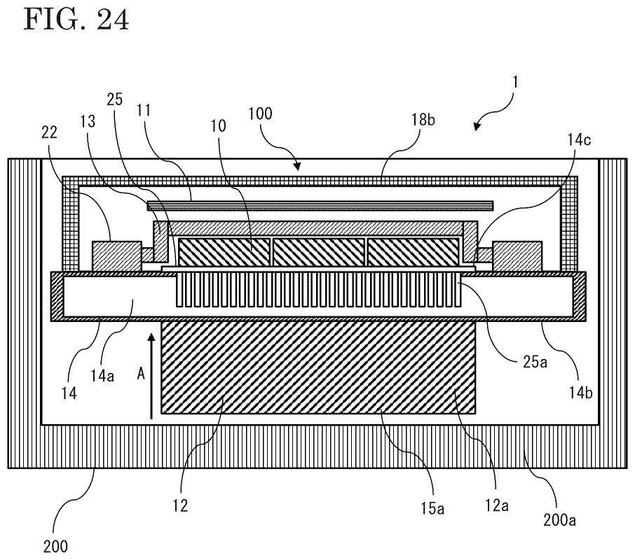

A power conversion device 1 according to embodiment 5 will be described. FIG. 21 is a side view schematically showing the power conversion device 1 according to embodiment 5, with the side wall of the cooler 14 being partially removed. FIG. 22 is a side view schematically showing the power conversion device 1, with the peripheral wall of the housing 200 being partially removed. FIG. 23 is a side view schematically showing another power conversion device 1 according to embodiment 5, with the side wall of the cooler 14 being partially removed. FIG. 24 is a side view schematically showing the other power conversion device 1, with the peripheral wall of the housing 200 being partially removed. The power conversion device 1 according to embodiment 5 has a configuration in which a second cover 18b has been added to the constituents in embodiment 1.

The power conversion device 1 includes one or both of: a first cover 18a provided to the first cooling surface 14b and covering all of members disposed on the first cooling surface 14b side; and a second cover 18b provided to the second cooling surface 14c and covering all of members disposed on the second cooling surface 14c side. In the present embodiment, the power conversion device 1 includes the second cover 18b as shown in FIG. 21. The second cover 18b is fixed to the cooler 14 through, for example, fastening with screws. The second cover 18b is formed from, for example, iron, an aluminum alloy, or a resin material. The second cover 18b has a through-hole (not shown) through which a wire to be connected to the DC power supply penetrates.

By this configuring, precision components (not shown) mounted on each of the power modules 10 and the control board 11 covered by the second cover 18b can be protected from dust, powder dust, and the like in a factory. A gasket (not shown) for sealing against a gap that might be generated between the second cover 18b and the cooler 14 may be provided between contact surfaces of the second cover 18b and the cooler 14. By providing the gasket, the members covered by the second cover 18b can be assuredly protected from dust, powder dust, and the like in a factory.

As shown in FIG. 22, in the present embodiment, the second cover 18b is disposed inward of an outer periphery of the second cooling surface 14c. By this configuring, work for mounting to the housing 200 can be easily performed even though the second cover 18b is provided. Since work for mounting to the housing 200 can be easily performed, the productivity for the power conversion device 1 can be improved.

### Modifications

Modifications of the power conversion device 1 will be described with reference to FIG. 23 and FIG. 24. FIG. 23 shows a modification of the power conversion device 1 shown in FIG. 21, and FIG. 24 shows a modification of the power conversion device 1 shown in FIG. 22. The cooler 14 has the opening provided in the first cooling surface or the second cooling surface and in communication with the coolant flow path 14a and the heat dissipation plate 25 covering the opening. In the present embodiment, the opening 14d is provided in the second cooling surface 14c. The heat dissipation plate 25 has, on the surface thereof on the coolant flow path 14a side, the plurality of heat dissipation fins 25a protruding to the coolant flow path 14a side. The heat dissipation plate 25 is formed from, for example, aluminum having excellent heat conducting properties.

The first cooling surface or the second cooling surface is formed on the surface of the heat dissipation plate 25 on the opposite side to the coolant flow path 14a side. The power module 10 is thermally connected to the first cooling surface or the second cooling surface on the heat dissipation plate 25. In the present embodiment, the second cooling surface 14c is formed on the surface of the heat dissipation plate 25 on the opposite side to the coolant flow path 14a side, and the power module 10 is thermally connected to the second cooling surface 14c on the heat dissipation plate 25. The second cover 18b is fixed to the second cooling surface 14c on the cooler 14 surrounding the opening 14d.

This configuring enables increase in the heat dissipation area in the coolant flow path 14a. Since the heat dissipation area is increased, the heat dissipation properties of the power module 10 can be improved. Since the heat dissipation properties of the power module 10 are improved, a power conversion device 1 having excellent cooling performance can be obtained. In addition, since the heat dissipation properties of the power module 10 are improved, the power conversion device 1 can be downsized.

### Embodiment 6

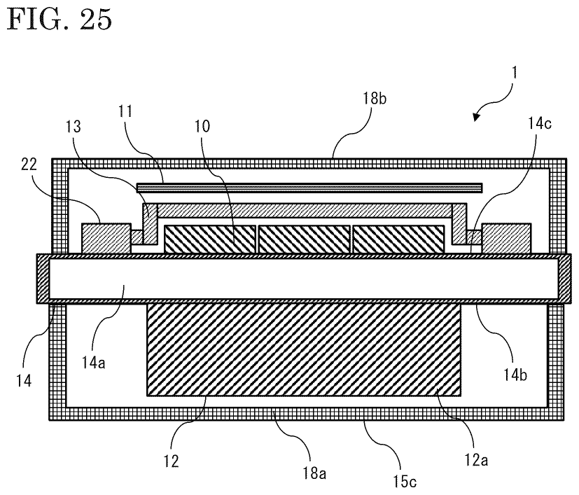

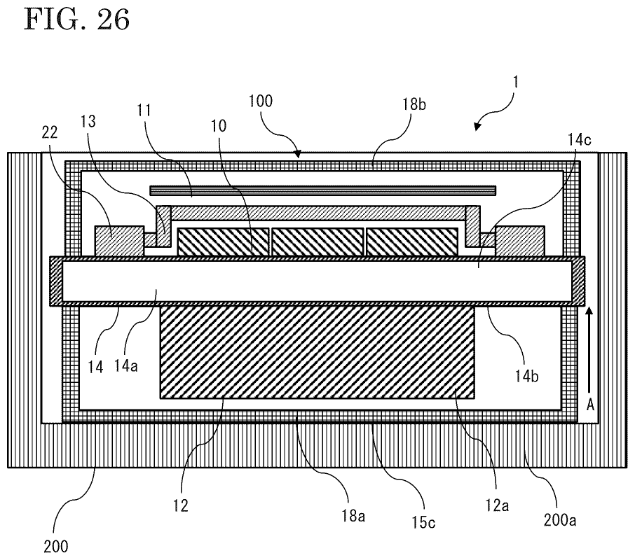

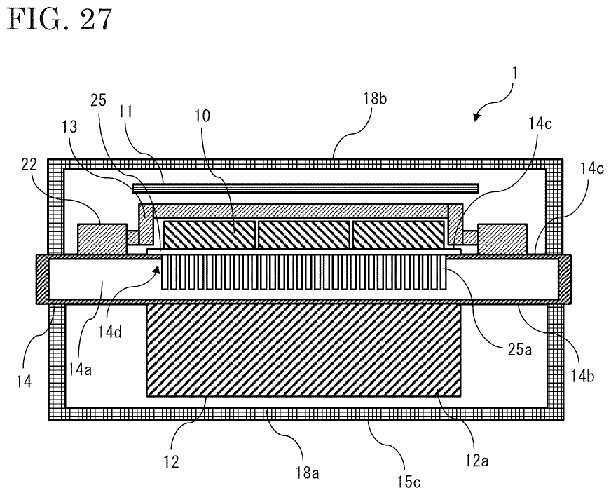

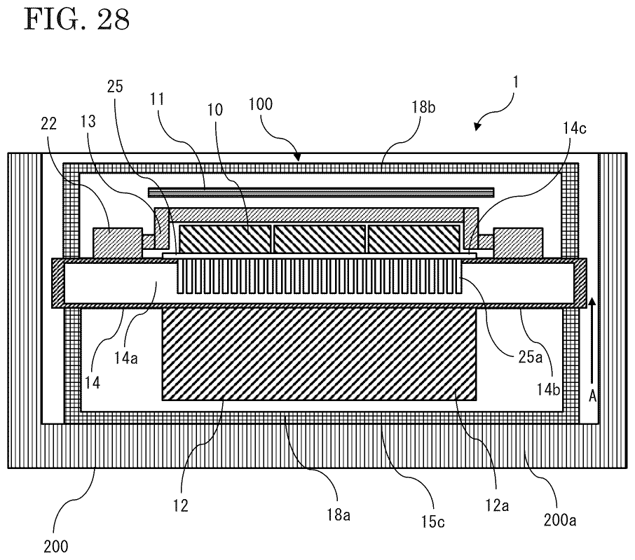

A power conversion device 1 according to embodiment 6 will be described. FIG. 25 is a side view schematically showing the power conversion device 1 according to embodiment 6, with the side wall of the cooler 14 being partially removed. FIG. 26 is a side view schematically showing the power conversion device 1, with the peripheral wall of the housing 200 being partially removed. FIG. 27 is a side view schematically showing another power conversion device 1 according to embodiment 6, with the side wall of the cooler 14 being partially removed. FIG. 28 is a side view schematically showing the other power conversion device 1, with the peripheral wall of the housing 200 being partially removed. The power conversion device 1 according to embodiment 6 has a configuration in which the first cover 18a and the second cover 18b have been added to the constituents in embodiment 1.

In the present embodiment, the power conversion device 1 includes both the first cover 18a and the second cover 18b as shown in FIG. 25. The first cover 18a is fixed to the cooler 14 through, for example, fastening with screws. The first cover 18a is formed from, for example, iron, an aluminum alloy, or a resin material.

The first cover 18a has a cover flat surface portion 15c formed at an end portion thereof on an opposite side to the first cooling surface 14b side parallelly to the first cooling surface 14b. This configuring enables the power conversion device 1 shown in FIG. 25 to stand on its own by the cover flat surface portion 15c which is a base surface. Since the power conversion device 1 stands on its own, stability at the time of transportation by a conveyor is improved during transportation of the power conversion device 1, for example. Thus, work for mounting to the housing 200 can be easily performed during the transportation. Since work for mounting to the housing 200 can be easily performed, the productivity for the power conversion device 1 can be improved. In addition, since work for mounting to the housing 200 becomes easy, the quality of the power conversion device 1 during assembling can be advantageously ensured.

A configuration in which the power conversion device 1 shown in FIG. 25 is accommodated in the housing 200 will be described with reference to FIG. 26. The power conversion device 1 shown in FIG. 25 is referred to as “sub-assembly 100” in FIG. 26. The power conversion device 1 includes the housing 200. The first cover 18a, the second cover 18b, and the cooler 14 are accommodated in the housing 200. The first cooling surface 14b and the second cooling surface 14c are orthogonal to the direction of the normal to the opposed surface of the housing 200 opposed to the first cooling surface 14b or the second cooling surface 14c. In the present embodiment, the housing 200 is formed in the shape of a tube with a bottom, and the opposed surface of the housing 200 is the inner surface of the bottom wall 200a of the housing 200. The shape of the housing 200 is not limited to the shape of a tube with a bottom. However, in the case where the housing 200 has the shape of a tube with a bottom, the housing 200 can be easily manufactured. The direction of the normal to the inner surface of the bottom wall 200a is the direction indicated by the arrow A in FIG. 26. The cover flat surface portion 15c is in contact with the inner surface of the bottom wall 200a of the housing 200. The sub-assembly 100 is fixed to the housing 200 by the cover flat surface portion 15c.

This configuring causes the mounting direction of the sub-assembly 100 to the housing 200 to be the direction orthogonal to the first cooling surface 14b and the second cooling surface 14c, whereby the sub-assembly 100 can be easily mounted to the housing 200. Since the sub-assembly 100 is easily mounted to the housing 200, the productivity for the power conversion device 1 can be improved. In addition, since the sub-assembly 100 can be fixed to the housing 200 by the cover flat surface portion 15c, the sub-assembly 100 can be easily fixed to the housing 200 without providing any other fixation members.

### Modifications

Modifications of the power conversion device 1 will be described with reference to FIG. 27 and FIG. 28. FIG. 27 shows a modification of the power conversion device 1 shown in FIG. 25, and FIG. 28 shows a modification of the power conversion device 1 shown in FIG. 26. The cooler 14 has the opening provided in the first cooling surface or the second cooling surface and in communication with the coolant flow path 14a and the heat dissipation plate 25 covering the opening. In the present embodiment, the opening 14d is provided in the second cooling surface 14c. The heat dissipation plate 25 has, on the surface thereof on the coolant flow path 14a side, the plurality of heat dissipation fins 25a protruding to the coolant flow path 14a side. The heat dissipation plate 25 is formed from, for example, aluminum having excellent heat conducting properties.

The first cooling surface or the second cooling surface is formed on the surface of the heat dissipation plate 25 on the opposite side to the coolant flow path 14a side. The power module 10 is thermally connected to the first cooling surface or the second cooling surface on the heat dissipation plate 25. In the present embodiment, the second cooling surface 14c is formed on the surface of the heat dissipation plate 25 on the opposite side to the coolant flow path 14a side, and the power module 10 is thermally connected to the second cooling surface 14c on the heat dissipation plate 25. The second cover 18b is fixed to the second cooling surface 14c on the cooler 14 surrounding the opening 14d.

This configuring enables increase in the heat dissipation area in the coolant flow path 14a. Since the heat dissipation area is increased, the heat dissipation properties of the power module 10 can be improved. Since the heat dissipation properties of the power module 10 are improved, a power conversion device 1 having excellent cooling performance can be obtained. In addition, since the heat dissipation properties of the power module 10 are improved, the power conversion device 1 can be downsized.

### Embodiment 7

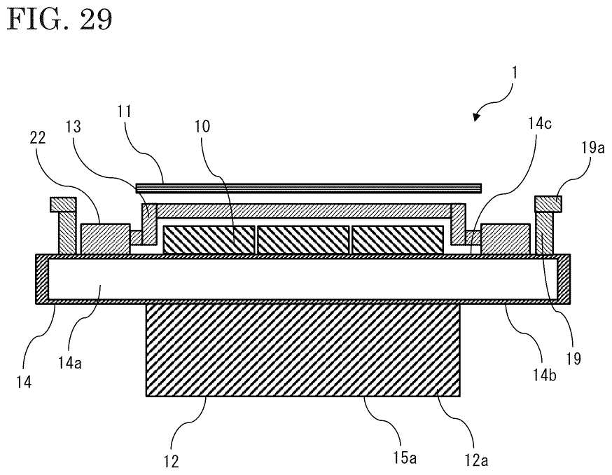

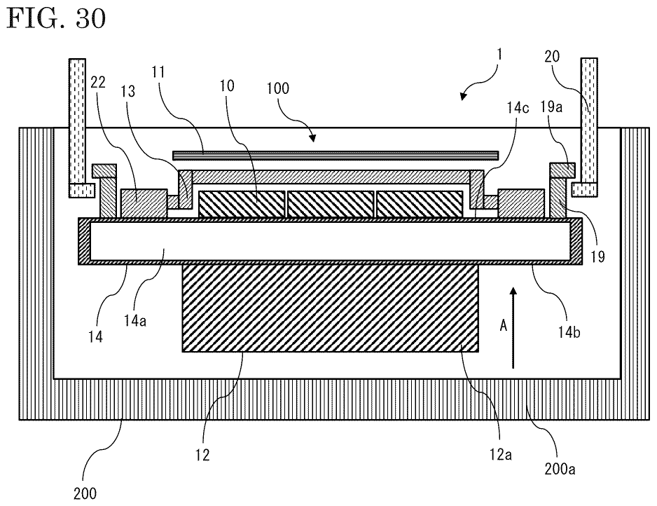

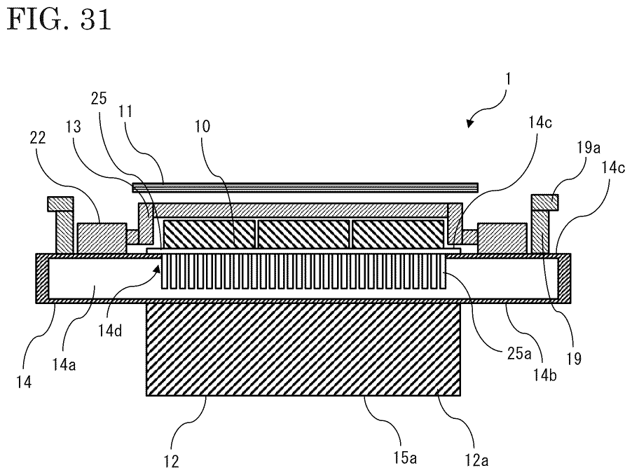

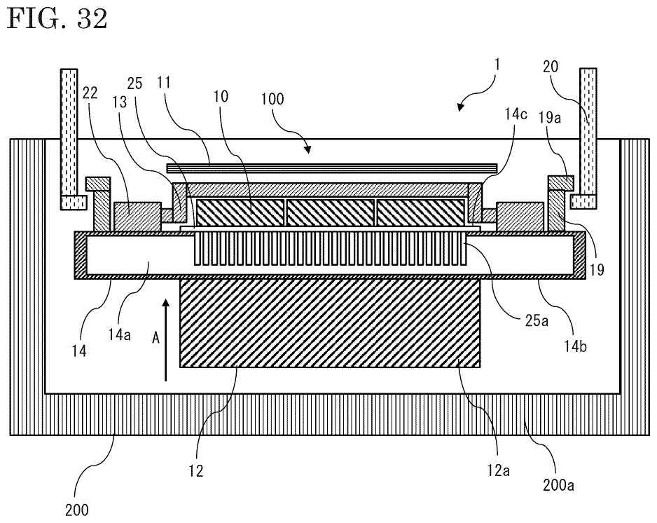

A power conversion device 1 according to embodiment 7 will be described. FIG. 29 is a side view schematically showing the power conversion device 1 according to embodiment 7, with the side wall of the cooler 14 being partially removed. FIG. 30 is a side view schematically showing the power conversion device 1, with the peripheral wall of the housing 200 being partially removed. FIG. 31 is a side view schematically showing another power conversion device 1 according to embodiment 7, with the side wall of the cooler 14 being partially removed. FIG. 32 is a side view schematically showing the other power conversion device 1, with the peripheral wall of the housing 200 being partially removed. The power conversion device 1 according to embodiment 7 has a configuration in which transportation protrusions 19 have been added to the constituents in embodiment 1.

As shown in FIG. 29, the second cooling surface 14c has a plurality of transportation protrusions 19 located inward of the outer periphery of the second cooling surface 14c and protruding in a direction away from the second cooling surface 14c. Each of the transportation protrusions 19 has, at an end portion thereof on the opposite side to the second cooling surface 14c side, a protrusion end portion 19a protruding to a direction parallel to the second cooling surface 14c. As shown in FIG. 30, the transportation protrusions 19 are portions that, as a result of gripping the protrusion end portions 19a thereof by a transportation device 20, serve as transportation means for transporting the sub-assembly 100 into the housing 200.

This configuring makes it possible to, since the transportation protrusions 19 are provided inward of the outermost periphery of the sub-assembly 100, ensure an operation region for the transportation device 20 and also decrease the clearance between the housing 200 and the sub-assembly 100. In addition, work for mounting the sub-assembly 100 to the housing 200 becomes easy, whereby the productivity for the power conversion device 1 can be improved. In addition, since work for mounting to the housing 200 becomes easy, the quality of the power conversion device 1 during assembling can be advantageously ensured.

The transportation protrusions 19 are formed from, for example, iron, an aluminum alloy, or a resin material. The transportation protrusions 19 are fixed to the cooler 14 through, for example, fastening with screws, fitting, adhesion, or welding. The transportation protrusions 19 and the cooler 14 may be integrated with each other.

The shape of the portion of each transportation protrusion 19 to be gripped by the transportation device 20 is not limited to the shape of the protrusion end portion 19a. The shape of the portion of the transportation protrusion 19 to be gripped by the transportation device 20 may be the shape of a recess to be fitted to an end portion of the transportation device 20.

### Modifications

Modifications of the power conversion device 1 will be described with reference to FIG. 31 and FIG. 32. FIG. 31 shows a modification of the power conversion device 1 shown in FIG. 29, and FIG. 32 shows a modification of the power conversion device 1 shown in FIG. 30. The cooler 14 has the opening provided in the first cooling surface or the second cooling surface and in communication with the coolant flow path 14a and the heat dissipation plate 25 covering the opening. In the present embodiment, the opening 14d is provided in the second cooling surface 14c. The heat dissipation plate 25 has, on the surface thereof on the coolant flow path 14a side, the plurality of heat dissipation fins 25a protruding to the coolant flow path 14a side. The heat dissipation plate 25 is formed from, for example, aluminum having excellent heat conducting properties.

The first cooling surface or the second cooling surface is formed on the surface of the heat dissipation plate 25 on the opposite side to the coolant flow path 14a side. The power module 10 is thermally connected to the first cooling surface or the second cooling surface on the heat dissipation plate 25. In the present embodiment, the second cooling surface 14c is formed on the surface of the heat dissipation plate 25 on the opposite side to the coolant flow path 14a side, and the power module 10 is thermally connected to the second cooling surface 14c on the heat dissipation plate 25. The transportation protrusions 19 are fixed to the second cooling surface 14c on the cooler 14 surrounding the opening 14d.

This configuring enables increase in the heat dissipation area in the coolant flow path 14a. Since the heat dissipation area is increased, the heat dissipation properties of the power module 10 can be improved. Since the heat dissipation properties of the power module 10 are improved, a power conversion device 1 having excellent cooling performance can be obtained. In addition, since the heat dissipation properties of the power module 10 are improved, the power conversion device 1 can be downsized.

### Embodiment 8

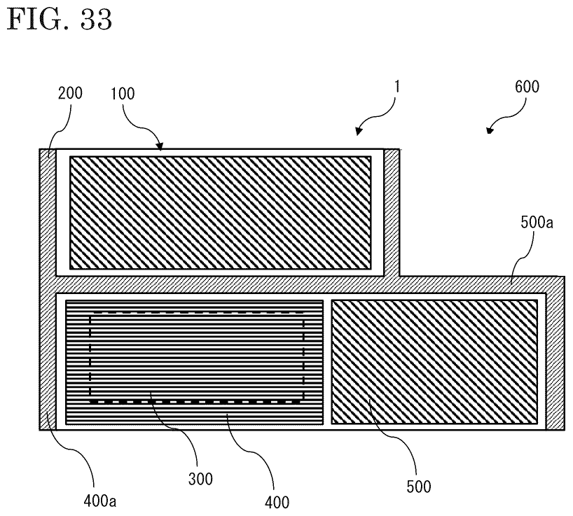

An electric vehicle drive device 600 according to embodiment 8 will be described. FIG. 33 is a diagram schematically showing the electric vehicle drive device 600 according to embodiment 8, with a side wall being partially removed. The electric vehicle drive device 600 according to embodiment 8 includes the power conversion device 1 having the housing 200.

The electric vehicle drive device 600 includes: the power conversion device 1 having the housing 200; an electric motor 400 electrically connected to the power conversion device 1 and having a rotation shaft, rotation of which is controlled; and a transmission 500 which is coupled to the rotation shaft and which converts a rotation speed of the rotation shaft and transmits a result of the conversion to a drive wheel. The housing 200 is integrated with one or both of an electric motor case 400a accommodating the electric motor 400 and a transmission case 500a accommodating the transmission 500. The electric motor 400 has the drive motor 300. The electric vehicle drive device 600 mounted in an electric vehicle is a device for transmitting rotation of the drive motor 300 controlled by the power conversion device 1 connected to the external DC power supply, via the transmission 500 to an axle of the electric vehicle. In the present embodiment, the electric motor case 400a and the transmission case 500a are integrated with each other, and the housing 200 is integrated with both the electric motor case 400a and the transmission case 500a.

The power conversion device 1 performs DC-AC conversion between the DC power supply (not shown) and the drive motor 300. The transmission 500 converts rotation of the drive motor 300 and transmits a result of the conversion to the axle. The housing 200, the electric motor case 400a, and the transmission case 500a are manufactured through, for example, aluminum die casting.

This configuring makes it possible to improve the vibration resistance of the power conversion device 1 as compared to a case where: the power conversion device 1, the electric motor 400, and the transmission 500 are accommodated in respective cases; and these cases are integrally fixed to one another. In addition, the number of components as cases can be decreased. Since the number of such components is decreased, cost for the electric vehicle drive device 600 can be decreased.

Although the disclosure is described above in terms Of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 power conversion device
10 power module
10a semiconductor element
11 control board
12 smoothing capacitor
12a case
12b capacitor element
13 busbar assembly
13a, 13b busbar
14 cooler
14a coolant flow path
14b first cooling surface
14c second cooling surface
14d opening
15a flat surface portion
15b support pillar flat surface portion
15c cover flat surface portion
16a, 16b support pillar
17 reactor
18a first cover
18b second cover
19 transportation protrusion
19a protrusion end portion
20 transportation device
21 DC power supply
22 power supply connection terminal
23 busbar
24 holding member
25 heat dissipation plate
25a heat dissipation fin
26 boost converter unit
27 buck converter unit
28 transmission control unit
100 sub-assembly
200 housing
200a bottom wall
300 drive motor
400 electric motor
400a electric motor case
500 transmission
500a transmission case
600 electric vehicle drive device

1. A power conversion device comprising:
one or a plurality of power modules, each of the power modules having one or a plurality of semiconductor elements and being connected to a power supply connection terminal to be connected to a DC power supply;
a control board which controls switching operations of the semiconductor elements;
at least one electrical component among an electrical component that is a smoothing capacitor which smooths an input voltage to be inputted from the DC power supply to the power module and electrical components that are a reactor, a boost converter unit, a buck converter unit, and a transmission control unit electrically connected to the power module;
a busbar assembly having a busbar establishing electrical connection in at least one interval among an interval between the power supply connection terminal and the power module, an interval between the power supply connection terminal and the at least one electrical component, and an interval between the power module and the at least one electrical component; and
a cooler having a first cooling surface, a second cooling surface on an opposite side to the first cooling surface, and a coolant flow path which is formed in the cooler, wherein
the power module, the smoothing capacitor, the reactor, the boost converter unit, the buck converter unit, the transmission control unit, and the busbar assembly are heat generation components,
the first cooling surface and the second cooling surface are provided on both sides of the coolant flow path parallelly to each other,
at least one of the heat generation components is thermally connected to the first cooling surface, and
at least one of the heat generation components is thermally connected to the second cooling surface.

2. The power conversion device according to claim 1, wherein the power conversion device has a power conversion function and a cooling function and enables inspection of the power conversion function and the cooling function.

3. The power conversion device according to claim 1, comprising a housing, wherein
the heat generation components, the control board, and the cooler are accommodated in the housing, and
the first cooling surface and the second cooling surface are orthogonal to a direction of a normal to an opposed surface of the housing opposed to the first cooling surface or the second cooling surface.

4. The power conversion device according to claim 3, wherein
the housing is formed in a shape of a tube with a bottom, and
the opposed surface is an inner surface of a bottom wall of the housing.

5. The power conversion device according to claim 1, wherein
the at least one heat generation component thermally connected to the first cooling surface has a flat surface portion formed on an opposite side to the first cooling surface side parallelly to the first cooling surface, and
neither the other heat generation components excluding the at least one heat generation component thermally connected to the first cooling surface nor the control board is provided on the opposite side to the first cooling surface side of the flat surface portion.

6. The power conversion device according to claim 1, comprising
a plurality of support pillars located on the first cooling surface side and protruding in a direction away from the first cooling surface, wherein
each of the plurality of support pillars has a support pillar flat surface portion formed at an end portion thereof on an opposite side to the first cooling surface side parallelly to the first cooling surface,
the support pillar flat surface portions are provided on a same plane parallel to the first cooling surface, and
neither the heat generation components nor the control board is provided on the opposite side to the first cooling surface side of each of the support pillar flat surface portions.

7. The power conversion device according to claim 6, wherein the plurality of support pillars are detachably provided.

8. The power conversion device according to claim 1, comprising one or both of:
a first cover provided to the first cooling surface and covering all of members disposed on the first cooling surface side; and
a second cover provided to the second cooling surface and covering all of members disposed on the second cooling surface side.

9. The power conversion device according to claim 8, comprising the first cover, wherein
the first cover has a cover flat surface portion formed at an end portion thereof on an opposite side to the first cooling surface side parallelly to the first cooling surface.

10. The power conversion device according to claim 1, wherein the second cooling surface has a plurality of transportation protrusions located inward of an outer periphery of the second cooling surface and protruding in a direction away from the second cooling surface.

11. The power conversion device according to claim 1, wherein the smoothing capacitor is thermally connected to the first cooling surface or the second cooling surface.

12. The power conversion device according to claim 1, wherein
the cooler has an opening provided in the first cooling surface or the second cooling surface and in communication with the coolant flow path and a heat dissipation plate covering the opening,
the heat dissipation plate has, on a surface thereof on the coolant flow path side, a plurality of heat dissipation fins protruding to the coolant flow path side,
the first cooling surface or the second cooling surface is formed on a surface of the heat dissipation plate on an opposite side to the coolant flow path side, and
the power module is thermally connected to the first cooling surface or the second cooling surface on the heat dissipation plate.

13. The power conversion device according to claim 6, comprising a housing, wherein
the heat generation components, the control board, the cooler, and the support pillars are accommodated in the housing,
the first cooling surface and the second cooling surface are orthogonal to a direction of a normal to an opposed surface of the housing opposed to the first cooling surface or the second cooling surface, and
the support pillar flat surface portions are in contact with the opposed surface.

14. The power conversion device according to claim 13, wherein
the housing is formed in a shape of a tube with a bottom, and
the opposed surface is an inner surface of a bottom wall of the housing.

15. The power conversion device according to claim 9, comprising a housing and the second cover, wherein
the first cover, the second cover, and the cooler are accommodated in the housing,
the first cooling surface and the second cooling surface are orthogonal to a direction of a normal to an opposed surface of the housing opposed to the first cooling surface or the second cooling surface, and
the cover flat surface portion is in contact with the opposed surface.

16. The power conversion device according to claim 15, wherein
the housing is formed in a shape of a tube with a bottom, and
the opposed surface is an inner surface of a bottom wall of the housing.

17. An electric vehicle drive device comprising:
the power conversion device according to claim 3;
an electric motor electrically connected to the power conversion device and having a rotation shaft, rotation of which is controlled; and
a transmission which is coupled to the rotation shaft and which converts a rotation speed of the rotation shaft and transmits a result of the conversion to a drive wheel, wherein
the housing is integrated with one or both of an electric motor case accommodating the electric motor and a transmission case accommodating the transmission.

18. A power conversion device manufacturing method comprising:
a member preparation step of preparing
one or a plurality of power modules, each of the power modules having one or a plurality of semiconductor elements and being connected to a power supply connection terminal to be connected to a DC power supply,
a control board which controls switching operations of the semiconductor elements,
a smoothing capacitor which smooths an input voltage to be inputted from the DC power supply to the power module,
a busbar assembly having a busbar establishing electrical connection in at least two of intervals between the power supply connection terminal, the power module, and the smoothing capacitor,
a cooler having a first cooling surface, a second cooling surface on an opposite side to the first cooling surface, and a coolant flow path which is formed in the cooler, and
a housing formed in a shape of a tube with a bottom;
a sub-assembly formation step of thermally connecting at least one of the power module, the smoothing capacitor, and the busbar assembly to the first cooling surface and thermally connecting at least one of the power module, the smoothing capacitor, and the busbar assembly to the second cooling surface to form a sub-assembly of a power conversion device from the power module, the control board, the smoothing capacitor, the busbar assembly, and the cooler; and
a housing mounting step of accommodating the sub-assembly in the housing, wherein
the first cooling surface and the second cooling surface are provided on both sides of the coolant flow path parallelly to each other,
the first cooling surface and the second cooling surface are orthogonal to a direction of a normal to an inner surface of a bottom wall of the housing, and
a mounting direction of the sub-assembly to the housing is a direction orthogonal to the first cooling surface and the second cooling surface.

19. The power conversion device manufacturing method according to claim 18, wherein
the sub-assembly has a power conversion function and a cooling function, and
the power conversion device manufacturing method comprises an inspection step of inspecting the power conversion function and the cooling function, the inspection step preceding the housing mounting step.

20. A power conversion device manufacturing method comprising:
a member preparation step of preparing
one or a plurality of power modules, each of the power modules having one or a plurality of semiconductor elements and being connected to a power supply connection terminal to be connected to a DC power supply,
a control board which controls switching operations of the semiconductor elements,
a smoothing capacitor which smooths an input voltage to be inputted from the DC power supply to the power module,
a busbar assembly having a busbar establishing electrical connection in at least two of intervals between the power supply connection terminal, the power module, and the smoothing capacitor,
a cooler having a first cooling surface, a second cooling surface on an opposite side to the first cooling surface, and a coolant flow path which is formed in the cooler,
a plurality of detachably formed support pillars, and
a housing formed in a shape of a tube with a bottom;
a sub-assembly formation step of thermally connecting at least one of the power module, the smoothing capacitor, and the busbar assembly to the first cooling surface, thermally connecting at least one of the power module, the smoothing capacitor, and the busbar assembly to the second cooling surface, and attaching the plurality of support pillars to the first cooling surface with the support pillars protruding in a direction away from the first cooling surface to form a sub-assembly of a power conversion device from the power module, the control board, the smoothing capacitor, the busbar assembly, the cooler, and the plurality of support pillars;
a transportation step of transporting the sub-assembly to a disposition location of the housing in a state where a support pillar flat surface portion provided to an end portion on an opposite side to the first cooling surface side of each of the plurality of support pillars has been brought into contact with a support surface so that the sub-assembly has been caused to stand;
a support pillar detachment step of detaching each of the plurality of support pillars from the sub-assembly; and
a housing mounting step of accommodating, in the housing, the sub-assembly from which the plurality of support pillars have been detached, wherein
after the sub-assembly formation step is performed, the support pillar flat surface portions in the sub-assembly are provided on a same plane parallel to the first cooling surface, and
after the sub-assembly formation step is performed, none of the power module, the smoothing capacitor, the busbar assembly, and the control board is provided on the opposite side to the first cooling surface side of each of the support pillar flat surface portions in the sub-assembly.
